(19) United States
(12) Patent Application Publication
(10) Pub. No.: US 2026/0290417 A1
(43) Pub. Date: Sep. 24, 2026

(54) SEMICONDUCTOR APPARATUS ADJUSTING A PHASE SKEW BETWEEN A CLOCK SIGNAL AND DATA

(71) Applicant: SK hynix Inc., Icheon-si Gyeonggi-do (KR)

(72) Inventors: Hyun Kyu PARK, Icheon-si Gyeonggi-do (KR); Sun Ki CHO, Icheon-si Gyeonggi-do (KR); Yang Ho SUR, Icheon-si Gyeonggi-do (KR); Ic Su OH, Icheon-si Gyeonggi-do (KR)

(73) Assignee: SK hynix Inc., Icheon-si Gyeonggi-do (KR)

(21) Appl. No.: 19/289,873

(22) Filed: Aug. 4, 2025

(30) Foreign Application Priority Data
Mar. 20, 2025 (KR) 10-2025-0035863

(51) Int. Cl. G11C 7/22; G11C 7/10

(52) U.S. Cl. CPC G11C 7/222; G11C 7/1066; G11C 7/1093; G11C 7/227

(57) ABSTRACT

A semiconductor apparatus monitors a first propagation delay through a clock distribution network and a read clock transmission circuit and a second propagation delay through the clock distribution network and a data transmission circuit. The semiconductor apparatus adjusts delay times of the read clock transmission circuit and the data transmission circuit such that a difference between the first propagation delay and the second propagation delay is within a predetermined time.

### CROSS-REFERENCES TO RELATED APPLICATION

The present application claims priority under 35 U.S.C. § 119(a) to Korean application number 10-2025-0035863 filed on Mar. 20, 2025, in the Korean Intellectual Property Office, which application is incorporated herein by reference in its entirety.

### BACKGROUND

### 1. Technical Field

Various embodiments generally relate to integrated circuit technology, and, more particularly, to a semiconductor apparatus adjusting a phase skew between a clock signal and data.

### 2. Related Art

An electronic device includes many electronic elements and a computer system, the electronic device including many semiconductor apparatuses each configured by a semiconductor. The semiconductor apparatuses constituting a computer system may communicate with each other by transmitting and receiving clock signals and data. The semiconductor apparatus can operate in synchronization with the clock signal. As the operating speed of the computer system and the frequency of the system clock signal increase, the pulse width of the system clock signal decreases, and the setup and hold margins for synchronizing the data signal to the system clock signal decrease.

A semiconductor apparatus, such as a memory apparatus, may generate a plurality of internal clock signals with different phases by dividing the system clock signal to increase the setup and hold margins for synchronizing the data signal. The semiconductor apparatus may synchronize the data signal in synchronization with each of the plurality of internal clock signals to increase the margin for sampling the data signal. Therefore, it is necessary to maintain a constant phase difference between the plurality of internal clock signals for the operational reliability of the semiconductor apparatus. However, the phase difference between the plurality of internal clock signals may change due to various factors. In particular, the plurality of internal clock signals may be propagated through internal paths of the semiconductor apparatus, and a skew and/or variation may occur in the phase difference between the plurality of internal clock signals.

### SUMMARY

In an embodiment, a semiconductor apparatus may include a clock receiving circuit, a clock distribution network, a first read clock transmission circuit, a first data transmission circuit, and a delay monitoring circuit. The clock receiving circuit may be configured to receive a first write clock signal and a second write clock signal and may be configured to generate a first internal clock signal, a second internal clock signal, a third internal clock signal, and a fourth internal clock signal. The clock distribution network may be configured to distribute the first to fourth internal clock signals as a first distribution clock signal, a second distribution clock signal, a third distribution clock signal, and a fourth distribution clock signal. The first read clock transmission circuit may be configured to generate a first read clock signal based on the first to fourth distribution clock signals and first dummy data. The first data transmission circuit may be configured to generate first data based on the first to fourth distribution clock signals and first internal data. The delay monitoring circuit may be configured to monitor a first propagation delay through the clock distribution network and the first read clock transmission circuit and a second propagation delay through the clock distribution network and the first data transmission circuit and may be configured to individually adjust a delay time of the first read clock transmission circuit and a delay time of the first data transmission circuit.

In an embodiment, a semiconductor apparatus may include a clock receiving circuit, a clock distribution network, a first read clock transmission circuit, a first data transmission circuit, and a delay monitoring circuit. The clock receiving circuit may be configured to receive a first write clock signal and a second write clock signal and configured to generate a first internal clock signal, a second internal clock signal, a third internal clock signal, and a fourth internal clock signal. The clock distribution network may be configured to distribute the first to fourth internal clock signals as a first distribution clock signal, a second distribution clock signal, a third distribution clock signal, and a fourth distribution clock signal in a normal mode and may be configured to output an oscillating signal as the first to fourth distribution clock signals in a monitoring mode. The first read clock transmission circuit may be configured to generate a first read clock signal and a first monitoring clock signal based on the first to fourth distribution clock signals and first dummy data and may be configured to have a delay time changed based on a first delay control signal. The first data transmission circuit may be configured to generate first data and a second monitoring clock signal based on the first to fourth distribution clock signals and first internal data and may be configured to have a delay time changed based on a second delay control signal. The delay monitoring circuit may be configured to generate the oscillating signal based on the first and second monitoring clock signals and may be configured to generate the first and second delay control signals based on the oscillating signal.

### BRIEF DESCRIPTION OF THE DRAWINGS

FIG. 1 is a diagram showing a configuration of a semiconductor system according to an embodiment of the present disclosure.

FIG. 2 is a diagram showing a configuration of a semiconductor apparatus according to an embodiment of the present disclosure.

FIG. 3 is a diagram showing a more detailed connection relationship among components of a semiconductor apparatus according to an embodiment of the present disclosure.

FIG. 4 is a diagram showing a configuration of a first data transmission circuit according to an embodiment of the present disclosure.

FIG. 5 is a diagram showing a configuration of a first variable delay buffer shown in FIG. 4.

FIG. 6A is a diagram showing a configuration of a data output circuit shown in FIG. 4.

FIG. 6B is a diagram showing a configuration of a data output circuit shown in FIG. 4.

FIG. 7 is a diagram showing a configuration of a delay monitoring circuit according to an embodiment of the present disclosure.

FIG. 8 is a diagram showing a configuration of an oscillating signal generation circuit according to an embodiment of the present disclosure.

FIG. 9A is a diagram showing a configuration of a set pulse generation circuit shown in FIG. 8.

FIG. 9B is a diagram showing a configuration of a reset pulse generation circuit shown in FIG. 8.

FIG. 10 is a diagram showing a configuration of an oscillating driver shown in FIG. 8.

FIG. 11 is a timing diagram showing an operation of an oscillating signal generation circuit according to an embodiment of the present disclosure.

FIGS. 12A-12C are timing diagrams showing operations of a semiconductor apparatus according to an embodiment of the present disclosure.

FIG. 13 is a diagram showing a configuration of a semiconductor system according to an embodiment of the present disclosure.

### DETAILED DESCRIPTION

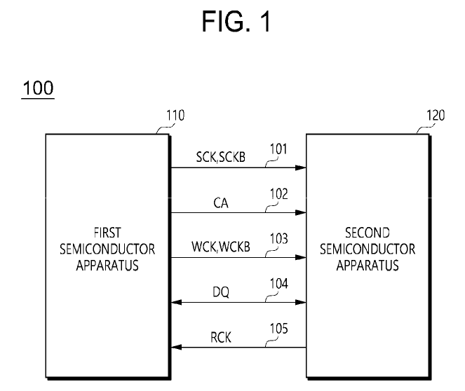

FIG. 1 is a diagram showing a configuration of a semiconductor system 100 according to an embodiment of the present disclosure. Referring to FIG. 1, the semiconductor system 100 may include a first semiconductor apparatus 110 and a second semiconductor apparatus 120. The first semiconductor apparatus 110 may be a master apparatus configured to provide various control signals required for the second semiconductor apparatus 120 to operate. The second semiconductor apparatus 120 may be a slave apparatus configured to perform various operations under the control of the first semiconductor apparatus 110. The first semiconductor apparatus 110 may include various types of host apparatuses. For example, the first semiconductor apparatus 110 may include a Central Processing Unit (CPU), a Graphic Processing Unit (GPU), a Multi-Media Processor (MMP), a Digital Signal Processor, an Application Processor (AP), and a memory controller. The second semiconductor apparatus 120 may be, for example, a memory apparatus, and the memory apparatus may include volatile memory and non-volatile memory. The volatile memory may include Static RAM (SRAM), Dynamic RAM (DRAM), and Synchronous DRAM (SDRAM), and the non-volatile memory may include Read Only Memory (ROM), Programmable ROM (PROM), Electrically Erasable and Programmable ROM (EEPROM), Erasable Programmable ROM (EPROM), flash memory, Phase change RAM (PRAM), Magnetic RAM (MRAM), Resistive RAM (RRAM), and Ferroelectric RAM (FRAM).

The second semiconductor apparatus 120 may be coupled to the first semiconductor apparatus 110 through a plurality of buses. The plurality of buses may be signal transmission paths, links, or channels for transmitting signals. The plurality of buses may include a first clock bus 101, a command address bus 102, a second clock bus 103, a data bus 104, and a third clock bus 105. The first clock bus 101, the command address bus 102, and the second clock bus 103 may be unidirectional buses from the first semiconductor apparatus 110 to the second semiconductor apparatus 120, the third clock bus 105 may be a unidirectional bus from the second semiconductor apparatus 120 to the first semiconductor apparatus 110, and the data bus 104 may be a bidirectional bus. The second semiconductor apparatus 120 may receive a system clock signal SCK through the first clock bus 101. In an embodiment, the system clock signal SCK may be transmitted along with a complementary system clock signal SCKB. The second semiconductor apparatus 120 may receive a command address signal CA from the first semiconductor apparatus 110 through the command address bus 102. The command address signal CA may include a plurality of bits. The first semiconductor apparatus 110 may transmit the command address signal CA synchronized with the system clock signal SCK, and the second semiconductor apparatus 120 may synchronize the command address signal CA with the system clock signal SCK. The second semiconductor apparatus 120 may receive a first write clock signal WCK and a second write clock signal WCKB from the first semiconductor apparatus 110 through the second clock bus 103. The second write clock signal WCKB may be a complementary signal having a phase opposite to that of the first write clock signal WCK. The second semiconductor apparatus 120 may receive data DQ from the first semiconductor apparatus 110 through the data bus 104 or may transmit data DQ to the first semiconductor apparatus 110. The first semiconductor apparatus 110 may transmit the data DQ, synchronized with the first and second write clock signals WCK and WCKB, to the second semiconductor apparatus 120. The second semiconductor apparatus 120 may transmit a first read clock signal RCK and a second read clock signal RCKB to the first semiconductor apparatus 110 through the third clock bus 105. The second semiconductor apparatus 120 may receive the first and second write clock signals WCK and WCKB from the first semiconductor apparatus 110 and may generate the first and second read clock signals RCK and RCKB based on the first and second write clock signals WCK and WCKB. The second semiconductor apparatus 120 may transmit the data DQ, synchronized with the first and second read clock signals RCK and RCKB, to the first semiconductor apparatus 110.

The first and second semiconductor apparatuses 110 and 120 may perform a write operation and a read operation. The write operation may refer to an operation in which the data is transmitted from the first semiconductor apparatus 110 to the second semiconductor apparatus 120, and the read operation may refer to an operation in which the data is transmitted from the second semiconductor apparatus 120 to the first semiconductor apparatus 110. When the write operation is performed, the first semiconductor apparatus 110 may transmit the command address signal CA corresponding to a write command signal to the second semiconductor apparatus 120. Thereafter, the first semiconductor apparatus 110 may transmit the first and second write clock signals WCK and WCKB to the second semiconductor apparatus 120 and may transmit the data DQ, synchronized with the first and second write clock signals WCK and WCKB, to the second semiconductor apparatus 120. The second semiconductor apparatus 120 may generate internal data of the second semiconductor apparatus 120 from the data DQ, synchronized with the first and second write clock signals WCK and WCKB. When the read operation is performed, the first semiconductor apparatus 110 may transmit the command address signal CA corresponding to a read command signal to the second semiconductor apparatus 120. The first semiconductor apparatus 110 may also transmit the first and second write clock signals WCK and WCKB to the second semiconductor apparatus 120. The second semiconductor apparatus 120 may prepare to output the internal data as the data DQ. For example, the second semiconductor apparatus 120 may output the internal data stored in a data storage region. The second semiconductor apparatus 120 may generate the first and second read clock signals RCK and RCKB based on the first and second write clock signals WCK and WCKB. The second semiconductor apparatus 120 may output the internal data as the data DQ, synchronized with the first and second read clock signals RCK and RCKB, and may output the first and second read clock signals RCK and RCKB together. The first semiconductor apparatus 110 may receive the data DQ, transmitted from the second semiconductor apparatus 120, the data DQ synchronized with the first and second read clock signals RCK and RCKB.

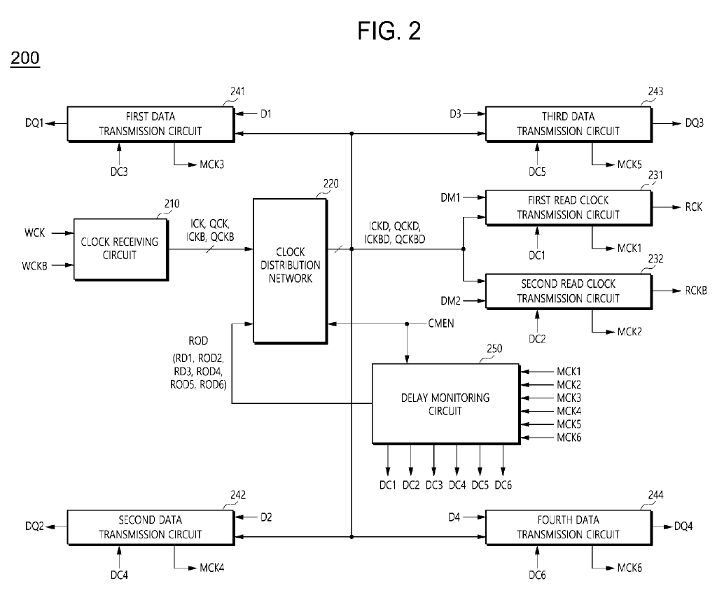

FIG. 2 is a diagram showing a configuration of a semiconductor apparatus 200 according to an embodiment of the present disclosure. The second semiconductor apparatus 120, shown in FIG. 1, may include the configuration of the semiconductor apparatus 200. The semiconductor apparatus 200 may receive the first write clock signal WCK and the second write clock signal WCKB from an external device (for example, the first semiconductor apparatus 110 shown in FIG. 1). The semiconductor apparatus 200 may transmit data to the external device. The semiconductor apparatus 200 may transmit at least one data to the external device, and without limitation, the number of data transmitted by the semiconductor apparatus 200 to the external device may be four. In an embodiment, the number of data transmitted by the semiconductor apparatus 200 to the external device may be less than or more than four. The semiconductor apparatus 200 may generate a read clock signal by receiving the first and second write clock signals WCK and WCKB and may output the data synchronized with the read clock signal. The semiconductor apparatus 200 may detect phase skews between a plurality of data and a plurality of read clock signals and may adjust the phase skews. For example, the semiconductor apparatus 200 may detect phase skews of the plurality of data and may adjust the phase skews of the plurality of data. The semiconductor apparatus 200 may detect phase skews of the plurality of read clock signals and may adjust the phase skews of the plurality of read clock signals. The semiconductor apparatus 200 may detect phase skews of the plurality of data with respect to the plurality of read clock signals and may adjust the phase skews of the plurality of data with respect to the plurality of read clock signals.

The semiconductor apparatus 200 may include a clock receiving circuit 210, a clock distribution network 220, a first read clock transmission circuit 231, a first data transmission circuit 241, and a delay monitoring circuit 250. The clock receiving circuit 210 may receive the first and second write clock signals WCK and WCKB and may generate a first internal clock signal ICK, a second internal clock signal QCK, a third internal clock signal ICKB, and a fourth internal clock signal QCKB. The clock receiving circuit 210 may receive the first and second write clock signals WCK and WCKB by differentially amplifying the first and second write clock signals WCK and WCKB. The clock receiving circuit 210 may generate the first to fourth internal clock signals ICK, QCK, ICKB, and QCKB by dividing the frequency of the first and second write clock signals WCK and WCKB. For example, the clock receiving circuit 210 may generate the first to fourth internal clock signals ICK, QCK, ICKB, and QCKB by dividing the frequency of the first and second write clock signals WCK and WCKB by two. The period of the first to fourth internal clock signals ICK, QCK, ICKB, and QCKB may be twice the period of the first and second write clock signals WCK and WCKB. The first to fourth internal clock signals ICK, QCK, ICKB, and QCKB may have a phase difference of 90 degrees with respect to subsequent internal clock signals (i.e., comparing first to second internal clock signals, second to third internal clock signals, third to fourth internal clock signals, and fourth to first internal clock signals). The first internal clock signal ICK may have a phase leading by 90 degrees relative to the second internal clock signal QCK. The second internal clock signal QCK may have a phase leading by 90 degrees relative to the third internal clock signal ICKB. The third internal clock signal ICKB may have a phase leading by 90 degrees relative to the fourth internal clock signal QCKB. The fourth internal clock signal QCKB may have a phase leading by 90 degrees relative to the first internal clock signal ICK.

The clock distribution network 220 may receive the first to fourth internal clock signals ICK, QCK, ICKB, and QCKB from the clock receiving circuit 210. The clock distribution network 220 may distribute and output the first to fourth internal clock signals ICK, QCK, ICKB, and QCKB as a first distribution clock signal ICKD, a second distribution clock signal QCKD, a third distribution clock signal ICKBD, and a fourth distribution clock signal QCKBD, respectively. The first distribution clock signal ICKD may have a logic level corresponding to the first internal clock signal ICK, and the second distribution clock signal QCKD may have a logic level corresponding to the second internal clock signal QCK. The third distribution clock signal ICKBD may have a logic level corresponding to the third internal clock signal ICKB, and the fourth distribution clock signal QCKBD may have a logic level corresponding to the fourth internal clock signal QCKB. The clock distribution network 220 may repeat the first to fourth internal clock signals ICK, QCK, ICKB, and QCKB to generate the first to fourth distribution clock signals ICKD, QCKD, ICKBD, and QCKBD and may distribute the first to fourth distribution clock signals ICKD, QCKD, ICKBD, and QCKBD to internal circuits of the semiconductor apparatus 200.

The clock distribution network 220 may distribute the first to fourth internal clock signals ICK, QCK, ICKB, and QCKB as the first to fourth distribution clock signals ICKD, QCKD, ICKBD, and QCKBD, respectively, in a normal mode. The clock distribution network 220 may receive an oscillating signal ROD from the delay monitoring circuit 250 and may output the oscillating signal ROD as the first to fourth distribution clock signals ICKD, QCKD, ICKBD, and QCKBD in a monitoring mode. The monitoring mode may refer to an operation mode for monitoring the propagation delay of a clock path and a data path in the semiconductor apparatus 200, and the normal mode may refer to any operation mode other than the monitoring mode. The clock distribution network 220 may further receive a clock monitoring enable signal CMEN. The clock monitoring enable signal CMEN may be enabled in the monitoring mode and may be disabled when the mode is not the monitoring mode. When the clock monitoring enable signal CMEN is disabled, the clock distribution network 220 may distribute the first to fourth internal clock signals ICK, QCK, ICKB, and QCKB as the first to fourth distribution clock signals ICKD, QCKD, ICKBD, and QCKBD, respectively. When the clock monitoring enable signal CMEN is enabled, the clock distribution network 220 may output the oscillating signal ROD as the first to fourth distribution clock signals ICKD, QCKD, ICKBD, and QCKBD instead of the first to fourth internal clock signals ICK, QCK, ICKB, and QCKB.

The first read clock transmission circuit 231 may receive the first to fourth distribution clock signals ICKD, QCKD, ICKBD, and QCKBD from the clock distribution network 220. The first read clock transmission circuit 231 may generate a first read clock signal RCK based on the first to fourth distribution clock signals ICKD, QCKD, ICKBD, and QCKBD. The first read clock transmission circuit 231 may further receive first dummy data DM1 and may generate the first read clock signal RCK based on the first dummy data DM1 and the first to fourth distribution clock signals ICKD, QCKD, ICKBD, and QCKBD. The first dummy data DM1 may have a fixed logic level. For example, the first dummy data DM1 may include four data signals, the odd-numbered data signals among the four having a first logic level and the even-numbered data signals among the four having a second logic level. The first logic level may be a high logic level, and the second logic level may be a low logic level. The first read clock transmission circuit 231 may sequentially output the four data signals of the first dummy data DM1 in synchronization with the first to fourth distribution clock signals ICKD, QCKD, ICKBD, and QCKBD, thereby generating the first read clock signal RCK. The first read clock transmission circuit 231 may transmit the first read clock signal RCK to the external device through the third clock bus 105, illustrated in FIG. 1. The frequency of the first read clock signal RCK may be higher than the frequency of the first to fourth distribution clock signals ICKD, QCKD, ICKBD, and QCKBD and may be substantially equal to the first and second write clock signals WCK and WCKB. The first read clock transmission circuit 231 may generate a first monitoring clock signal MCK1 to monitor propagation delay caused by the clock distribution network 220 and the first read clock transmission circuit 231. The first read clock transmission circuit 231 may generate the first read clock signal RCK in the normal mode and may generate the first monitoring clock signal MCK1 in the monitoring mode. The first read clock transmission circuit 231 may generate the first monitoring clock signal MCK1 based on the first to fourth distribution clock signals ICKD, QCKD, ICKBD, and QCKBD and the first dummy data DM1. The period of the first monitoring clock signal MCK1 may correspond to a propagation delay time through the clock distribution network 220 and the first read clock transmission circuit 231. The first read clock transmission circuit 231 may provide the first monitoring clock signal MCK1 to the delay monitoring circuit 250. The first read clock transmission circuit 231 may receive a first delay control signal DC1. A delay time of the first read clock transmission circuit 231 may be adjusted based on the first delay control signal DC1.

The semiconductor apparatus 200 may further include a second read clock transmission circuit 232. The second read clock transmission circuit 232 may receive the first to fourth distribution clock signals ICKD, QCKD, ICKBD, and QCKBD from the clock distribution network 220 and may generate a second read clock signal RCKB based on the first to fourth distribution clock signals ICKD, QCKD, ICKBD, and QCKBD. The second read clock transmission circuit 232 may further receive a second dummy data DM2 and may generate the second read clock signal RCKB based on the second dummy data DM2 and the first to fourth distribution clock signals ICKD, QCKD, ICKBD, and QCKBD. The second dummy data DM2 may have a fixed logic level and may have a logic level opposite to that of the first dummy data DM1. For example, the second dummy data DM2 may include four data signals. Odd-numbered data signals among the four may have the second logic level, and even-numbered data signals among the four may have the first logic level. The second read clock transmission circuit 232 may sequentially output the four data signals of the second dummy data DM2 in synchronization with the first to fourth distribution clock signals ICKD, QCKD, ICKBD, and QCKBD, thereby generating the second read clock signal RCKB. The second read clock transmission circuit 232 may transmit the second read clock signal RCKB to the external device through the third clock bus 105, illustrated in FIG. 1. The second read clock signal RCKB may be a complementary signal having a logic level opposite to that of the first read clock signal RCK. The frequency of the second read clock signal RCKB may be higher than the frequency of the first to fourth distribution clock signals ICKD, QCKD, ICKBD, and QCKBD and may be substantially equal to the first and second write clock signals WCK and WCKB. The second read clock transmission circuit 232 may generate a second monitoring clock signal MCK2 to monitor propagation delay caused by the clock distribution network 220 and the second read clock transmission circuit 232. The second read clock transmission circuit 232 may generate the second read clock signal RCKB in the normal mode and may generate the second monitoring clock signal MCK2 in the monitoring mode. The second read clock transmission circuit 232 may generate the second monitoring clock signal MCK2 based on the first to fourth distribution clock signals ICKD, QCKD, ICKBD, and QCKBD and the second dummy data DM2. The period of the second monitoring clock signal MCK2 may correspond to a propagation delay time through the clock distribution network 220 and the second read clock transmission circuit 232. The second read clock transmission circuit 232 may provide the second monitoring clock signal MCK2 to the delay monitoring circuit 250. The second read clock transmission circuit 232 may receive a second delay control signal DC2. A delay time of the second read clock transmission circuit 232 may be adjusted based on the second delay control signal DC2.

The first data transmission circuit 241 may receive the first to fourth distribution clock signals ICKD, QCKD, ICKBD, and QCKBD from the clock distribution network 220. The first data transmission circuit 241 may receive first internal data D1 and may generate first data DQ1 based on the first internal data D1 and the first to fourth distribution clock signals ICKD, QCKD, ICKBD, and QCKBD. For example, the first internal data D1 may include four data signals. The first data transmission circuit 241 may sequentially output the four data signals of the first internal data D1 in synchronization with the first to fourth distribution clock signals ICKD, QCKD, ICKBD, and QCKBD, thereby generating the first data DQ1. The first data transmission circuit 241 may transmit the first data DQ1 to the external device through the data bus 104, illustrated in FIG. 1. The first data transmission circuit 241 may generate the first data DQ1 in the normal mode and may generate a third monitoring clock signal MCK3 in the monitoring mode. The first data transmission circuit 241 may generate the third monitoring clock signal MCK3 based on the first to fourth distribution clock signals ICKD, QCKD, ICKBD, and QCKBD and the first internal data D1. When the first data transmission circuit 241 generates the third monitoring clock signal MCK3, the first internal data D1 may have a predetermined logic level. The word “predetermined” as used herein with respect to a parameter, such as a predetermined timing, time, or voltage level, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm. The period of the third monitoring clock signal MCK3 may correspond to a propagation delay time through the clock distribution network 220 and the first data transmission circuit 241. The first data transmission circuit 241 may provide the third monitoring clock signal MCK3 to the delay monitoring circuit 250. The first data transmission circuit 241 may receive a third delay control signal DC3. A delay time of the first data transmission circuit 241 may be adjusted based on the third delay control signal DC3.

The semiconductor apparatus 200 may further include a second data transmission circuit 242, a third data transmission circuit 243, and a fourth data transmission circuit 244. The second data transmission circuit 242 may receive the first to fourth distribution clock signals ICKD, QCKD, ICKBD, and QCKBD from the clock distribution network 220. The second data transmission circuit 242 may receive second internal data D2 and may generate second data DQ2 based on the second internal data D2 and the first to fourth distribution clock signals ICKD, QCKD, ICKBD, and QCKBD. For example, the second internal data D2 may include four data signals. The second data transmission circuit 242 may sequentially output the four data signals of the second internal data D2 in synchronization with the first to fourth distribution clock signals ICKD, QCKD, ICKBD, and QCKBD, thereby generating the second data DQ2. The second data transmission circuit 242 may transmit the second data DQ2 to the external device through the data bus 104, illustrated in FIG. 1. The second data transmission circuit 242 may generate the second data DQ2 in the normal mode and may generate a fourth monitoring clock signal MCK4 in the monitoring mode. The second data transmission circuit 242 may be configured to generate the fourth monitoring clock signal MCK4 based on the first to fourth distribution clock signals ICKD, QCKD, ICKBD, and QCKBD and the second internal data D2. When the second data transmission circuit 242 generates the fourth monitoring clock signal MCK4, the second internal data D2 may have a predetermined logic level. The period of the fourth monitoring clock signal MCK4 may correspond to a propagation delay time through the clock distribution network 220 and the second data transmission circuit 242. The second data transmission circuit 242 may provide the fourth monitoring clock signal MCK4 to the delay monitoring circuit 250. The second data transmission circuit 242 may receive a fourth delay control signal DC4. A delay time of the second data transmission circuit 242 may be adjusted based on the fourth delay control signal DC4.

The third data transmission circuit 243 may receive the first to fourth distribution clock signals ICKD, QCKD, ICKBD, and QCKBD from the clock distribution network 220. The third data transmission circuit 243 may receive third internal data D3 and may generate third data DQ3 based on the third internal data D3 and the first to fourth distribution clock signals ICKD, QCKD, ICKBD, and QCKBD. For example, the third internal data D3 may include four data signals. The third data transmission circuit 243 may sequentially output the four data signals of the third internal data D3 in synchronization with the first to fourth distribution clock signals ICKD, QCKD, ICKBD, and QCKBD, thereby generating the third data DQ3. The third data transmission circuit 243 may transmit the third data DQ3 to the external device through the data bus 104, illustrated in FIG. 1. The third data transmission circuit 243 may generate the third data DQ3 in the normal mode and may generate a fifth monitoring clock signal MCK5 in the monitoring mode. The third data transmission circuit 243 may generate the fifth monitoring clock signal MCK5 based on the first to fourth distribution clock signals ICKD, QCKD, ICKBD, and QCKBD and the third internal data D3. When the third data transmission circuit 243 generates the fifth monitoring clock signal MCK5, the third internal data D3 may have a predetermined logic level. The period of the fifth monitoring clock signal MCK5 may correspond to a propagation delay time through the clock distribution network 220 and the third data transmission circuit 243. The third data transmission circuit 243 may provide the fifth monitoring clock signal MCK5 to the delay monitoring circuit 250. The third data transmission circuit 243 may receive a fifth delay control signal DC5. A delay time of the third data transmission circuit 243 may be changed based on the fifth delay control signal DC5.

The fourth data transmission circuit 244 may receive the first to fourth distribution clock signals ICKD, QCKD, ICKBD, and QCKBD from the clock distribution network 220. The fourth data transmission circuit 244 may receive fourth internal data D4 and may generate fourth data DQ4 based on the fourth internal data D4 and the first to fourth distribution clock signals ICKD, QCKD, ICKBD, and QCKBD. For example, the fourth internal data D4 may include four data signals. The fourth data transmission circuit 244 may sequentially output the four data signals of the fourth internal data D4 in synchronization with the first to fourth distribution clock signals ICKD, QCKD, ICKBD, and QCKBD, thereby generating the fourth data DQ4. The fourth data transmission circuit 244 may transmit the fourth data DQ4 to the external device through the data bus 104 illustrated in FIG. 1. The fourth data transmission circuit 244 may generate the fourth data DQ4 in the normal mode and may generate a sixth monitoring clock signal MCK6 in the monitoring mode. The fourth data transmission circuit 244 may generate the sixth monitoring clock signal MCK6 based on the first to fourth distribution clock signals ICKD, QCKD, ICKBD, and QCKBD and the fourth internal data D4. When the fourth data transmission circuit 244 generates the sixth monitoring clock signal MCK6, the fourth internal data D4 may have a predetermined logic level. The period of the sixth monitoring clock signal MCK6 may correspond to a propagation delay time through the clock distribution network 220 and the fourth data transmission circuit 244. The fourth data transmission circuit 244 may provide the sixth monitoring clock signal MCK6 to the delay monitoring circuit 250. The fourth data transmission circuit 244 may receive a sixth delay control signal DC6. A delay time of the fourth data transmission circuit 244 may be adjusted based on the sixth delay control signal DC6.

The delay monitoring circuit 250 may monitor propagation delays from the clock distribution network 220 to internal circuits of the semiconductor apparatus 200, respectively. The delay monitoring circuit 250 may monitor a first propagation delay caused by the clock distribution network 220 and the first read clock transmission circuit 231. The delay monitoring circuit 250 may form a first closed loop and/or a first oscillating path with the clock distribution network 220 and the first read clock transmission circuit 231 to monitor the first propagation delay and may adjust a delay time of the first read clock transmission circuit 231. The delay monitoring circuit 250 may monitor a second propagation delay caused by the clock distribution network 220 and the second read clock transmission circuit 232. The delay monitoring circuit 250 may form a second closed loop and/or a second oscillating path with the clock distribution network 220 and the second read clock transmission circuit 232 to monitor the second propagation delay and may adjust a delay time of the second read clock transmission circuit 232. The delay monitoring circuit 250 may monitor a third propagation delay caused by the clock distribution network 220 and the first data transmission circuit 241. The delay monitoring circuit 250 may form a third closed loop and/or a third oscillating path with the clock distribution network 220 and the first data transmission circuit 241 to monitor the third propagation delay and may adjust a delay time of the first data transmission circuit 241. The delay monitoring circuit 250 may monitor a fourth propagation delay caused by the clock distribution network 220 and the second data transmission circuit 242. The delay monitoring circuit 250 may form a fourth closed loop and/or a fourth oscillating path with the clock distribution network 220 and the second data transmission circuit 242 to monitor the fourth propagation delay and may adjust a delay time of the second data transmission circuit 242. The delay monitoring circuit 250 may monitor a fifth propagation delay caused by the clock distribution network 220 and the third data transmission circuit 243. The delay monitoring circuit 250 may form a fifth closed loop and/or a fifth oscillating path with the clock distribution network 220 and the third data transmission circuit 243 to monitor the fifth propagation delay and may adjust a delay time of the third data transmission circuit 243. The delay monitoring circuit 250 may monitor a sixth propagation delay caused by the clock distribution network 220 and the fourth data transmission circuit 244. The delay monitoring circuit 250 may form a sixth closed loop and/or a sixth oscillating path with the clock distribution network 220 and the fourth data transmission circuit 244 to monitor the sixth propagation delay and may adjust a delay time of the fourth data transmission circuit 244. The delay monitoring circuit 250 may form the first to sixth closed loops and/or oscillating paths in a monitoring mode and may monitor the first to sixth propagation delays, respectively. The delay monitoring circuit 250 may receive the clock monitoring enable signal CMEN and may perform the monitoring operation when the clock monitoring enable signal CMEN is enabled.

The delay monitoring circuit 250 may monitor the first to sixth propagation delays, respectively, and may individually adjust delay times of the first and second read clock transmission circuits 231 and 232 and the first to fourth data transmission circuits 241, 242, 243, and 244 based on monitoring results of the first to sixth propagation delays. For example, the delay monitoring circuit 250 may adjust delay times of the first and second read clock transmission circuits 231 and 232 and the first to fourth data transmission circuits 241, 242, 243, and 244 so that time differences among the propagation delays are maintained within a predetermined time. The delay monitoring circuit 250 may adjust delay times so that a difference between one of the third to sixth propagation delays and one of the first and second propagation delays is less than or equal to a first time. For example, the delay monitoring circuit 250 may adjust delay times of the first read clock transmission circuit 231 and the first data transmission circuit 241 so that a difference between the first propagation delay and the third propagation delay is less than or equal to the first time. The delay monitoring circuit 250 may adjust delay times of the first read clock transmission circuit 231 and the second data transmission circuit 242 so that a difference between the first propagation delay and the fourth propagation delay is less than or equal to the first time. The delay monitoring circuit 250 may adjust delay times of the first read clock transmission circuit 231 and the third data transmission circuit 243 so that a difference between the first propagation delay and the fifth propagation delay is less than or equal to the first time. The delay monitoring circuit 250 may adjust delay times of the first read clock transmission circuit 231 and the fourth data transmission circuit 244 so that a difference between the first propagation delay and the sixth propagation delay is less than or equal to the first time. The delay monitoring circuit 250 may adjust delay times of the first and second read clock transmission circuits 231 and 232 so that the first and second propagation delays are substantially identical. The delay monitoring circuit 250 may adjust delay times of the first data transmission circuit 241 and the second data transmission circuit 242 so that a difference between the third propagation delay and the fourth propagation delay is less than or equal to a second time. The delay monitoring circuit 250 may adjust delay times of the first data transmission circuit 241 and the third data transmission circuit 243 so that a difference between the third propagation delay and the fifth propagation delay is less than or equal to the second time. The delay monitoring circuit 250 may adjust delay times of the first data transmission circuit 241 and the fourth data transmission circuit 244 so that a difference between the third propagation delay and the sixth propagation delay is less than or equal to the second time. The second time may be different from the first time.

The delay monitoring circuit 250 may receive the first monitoring clock signal MCK1 from the first read clock transmission circuit 231. The delay monitoring circuit 250 may receive the second monitoring clock signal MCK2 from the second read clock transmission circuit 232. The delay monitoring circuit 250 may receive the third monitoring clock signal MCK3 from the first data transmission circuit 241. The delay monitoring circuit 250 may receive the fourth monitoring clock signal MCK4 from the second data transmission circuit 242. The delay monitoring circuit 250 may receive the fifth monitoring clock signal MCK5 from the third data transmission circuit 243. The delay monitoring circuit 250 may receive the sixth monitoring clock signal MCK6 from the fourth data transmission circuit 244. The delay monitoring circuit 250 may generate the oscillating signal ROD based on the first to sixth monitoring clock signals MCK1, MCK2, MCK3, MCK4, MCK5, and MCK6. The oscillating signal ROD may include first to sixth oscillating signals ROD1, ROD2, ROD3, ROD4, ROD5, and ROD6. The delay monitoring circuit 250 may form an oscillating path with the clock distribution network 220 and the first read clock transmission circuit 231, receive the first monitoring clock signal MCK1, and generate the first oscillating signal ROD1. The delay monitoring circuit 250 may form an oscillating path with the clock distribution network 220 and the second read clock transmission circuit 232, receive the second monitoring clock signal MCK2, and generate the second oscillating signal ROD2. The delay monitoring circuit 250 may form an oscillating path with the clock distribution network 220 and the first data transmission circuit 241, receive the third monitoring clock signal MCK3, and generate the third oscillating signal ROD3. The delay monitoring circuit 250 may form an oscillating path with the clock distribution network 220 and the second data transmission circuit 242, receive the fourth monitoring clock signal MCK4, and generate the fourth oscillating signal ROD4. The delay monitoring circuit 250 may form an oscillating path with the clock distribution network 220 and the third data transmission circuit 243, receive the fifth monitoring clock signal MCK5, and generate the fifth oscillating signal ROD5. The delay monitoring circuit 250 may form an oscillating path with the clock distribution network 220 and the fourth data transmission circuit 244, receive the sixth monitoring clock signal MCK6, and generate the sixth oscillating signal ROD6.

The delay monitoring circuit 250 may individually generate the first to sixth delay control signals DC1, DC2, DC3, DC4, DC5, and DC6 based on the oscillating signal ROD. The delay monitoring circuit 250 may detect periods of the first to sixth oscillating signals ROD1, ROD2, ROD3, ROD4, ROD5, and ROD6, respectively, and may generate the first to sixth delay control signals DC1, DC2, DC3, DC4, DC5, and DC6. The delay monitoring circuit 250 may detect the periods of the first to sixth oscillating signals ROD1, ROD2, ROD3, ROD4, ROD5, and ROD6 by counting edges of the first to sixth oscillating signals ROD1, ROD2, ROD3, ROD4, ROD5, and ROD6 for a predetermined number of times. The delay monitoring circuit 250 may generate the first to sixth delay control signals DC1, DC2, DC3, DC4, DC5, and DC6 based on differences in periods of the first to sixth oscillating signals ROD1, ROD2, ROD3, ROD4, ROD5, and ROD6. For example, the delay monitoring circuit 250 may set the first oscillating signal ROD1 as a reference signal and may generate the second delay control signal DC2 based on a difference in period between the first and second oscillating signals ROD1 and ROD2. The delay monitoring circuit 250 may set the second oscillating signal ROD2 as a reference signal and may generate the first delay control signal DC1 based on a difference in period between the first and second oscillating signals ROD1 and ROD2. The delay monitoring circuit 250 may set one of the first and second oscillating signals ROD1 and ROD2 as a reference signal and may generate the third delay control signal DC3 based on a difference in period between the reference signal and the third oscillating signal ROD3. The delay monitoring circuit 250 may generate the fourth delay control signal DC4 based on a difference in period between the reference signal and the fourth oscillating signal ROD4. The delay monitoring circuit 250 may generate the fifth delay control signal DC5 based on a difference in period between the reference signal and the fifth oscillating signal ROD5. The delay monitoring circuit 250 may generate the sixth delay control signal DC6 based on a difference in period between the reference signal and the sixth oscillating signal ROD6. The delay monitoring circuit 250 may set the third oscillating signal ROD3 as a reference signal and may generate the fourth delay control signal DC4 based on a difference in period between the third oscillating signal ROD3 and the fourth oscillating signal ROD4. The delay monitoring circuit 250 may generate the fifth delay control signal DC5 based on a difference in period between the third oscillating signal ROD3 and the fifth oscillating signal ROD5. The delay monitoring circuit 250 may generate the sixth delay control signal DC6 based on a difference in period between the third oscillating signal ROD3 and the sixth oscillating signal ROD6.

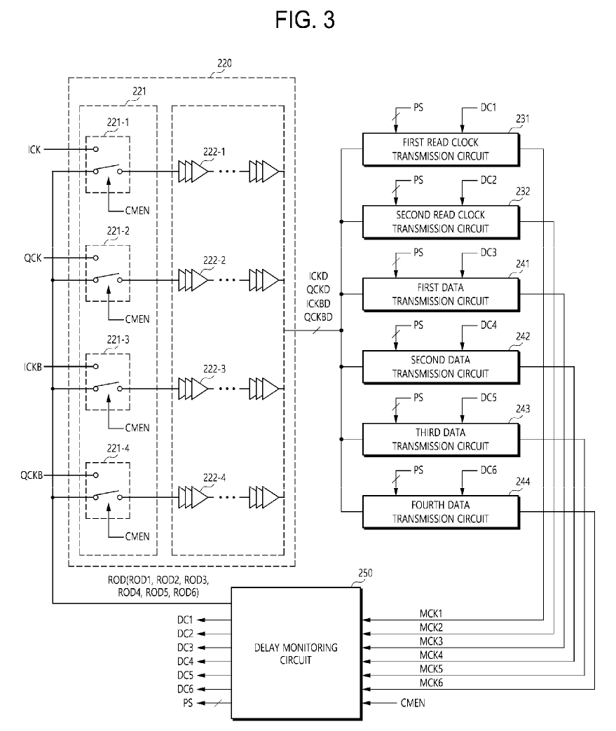

FIG. 3 is a diagram showing a more detailed connection relationship among components of the semiconductor apparatus 200 according to an embodiment of the present disclosure. Referring to FIG. 3, the clock distribution network 220 may include a switching circuit 221 and a repeater circuit 222. The switching circuit 221 may receive the first to fourth internal clock signals ICK, QCK, ICKB, and QCKB, the oscillating signal ROD, and the clock monitoring enable signal CMEN and may output the first to fourth internal clock signals ICK, QCK, ICKB, and QCKB or the oscillating signal ROD based on the clock monitoring enable signal CMEN. The switching circuit 221 may output the first to fourth internal clock signals ICK, QCK, ICKB, and QCKB to the repeater circuit 222 when the clock monitoring enable signal CMEN is disabled. The switching circuit 221 may output the oscillating signal ROD to the repeater circuit 222 when the clock monitoring enable signal CMEN is enabled. The repeater circuit 222 may generate the first to fourth distribution clock signals ICKD, QCKD, ICKBD, and QCKBD by repeating an output signal of the switching circuit 221. When the first to fourth internal clock signals ICK, QCK, ICKB, and QCKB are output from the switching circuit 221, the repeater circuit 222 may repeat the first to fourth internal clock signals ICK, QCK, ICKB, and QCKB, respectively, and may generate the first to fourth distribution clock signals ICKD, QCKD, ICKBD, and QCKBD. When the oscillating signal ROD is output from the switching circuit 221, the repeater circuit 222 may repeat the oscillating signal ROD and may generate the first to fourth signals ICKD, QCKD, ICKBD, and QCKBD.

The switching circuit 221 may include a first switch 221-1, a second switch 221-2, a third switch 221-3, and a fourth switch 221-4. The first switch 221-1 may receive the first internal clock signal ICK, the oscillating signal ROD, and the clock monitoring enable signal CMEN and may output one of the first internal clock signal ICK and the oscillating signal ROD based on the clock monitoring enable signal CMEN. The second switch 221-2 may receive the second internal clock signal QCK, the oscillating signal ROD, and the clock monitoring enable signal CMEN and may output one of the second internal clock signal QCK and the oscillating signal ROD based on the clock monitoring enable signal CMEN. The third switch 221-3 may receive the third internal clock signal ICKB, the oscillating signal ROD, and the clock monitoring enable signal CMEN and may output one of the third internal clock signal ICKB and the oscillating signal ROD based on the clock monitoring enable signal CMEN. The fourth switch 221-4 may receive the fourth internal clock signal QCKB, the oscillating signal ROD, and the clock monitoring enable signal CMEN and may output one of the fourth internal clock signal QCKB and the oscillating signal ROD based on the clock monitoring enable signal CMEN. When the clock monitoring enable signal CMEN is disabled, the first to fourth switches 221-1, 221-2, 221-3, and 221-4 may respectively output the first to fourth internal clock signals ICK, QCK, ICKB, and QCKB to the repeater circuit 222. When the clock monitoring enable signal CMEN is enabled, the first to fourth switches 221-1, 221-2, 221-3, and 221-4 may respectively output the oscillating signal ROD to the repeater circuit 222 instead of the first to fourth internal clock signals ICK, QCK, ICKB, and QCKB.

The repeater circuit 222 may include a first repeater 222-1, a second repeater 222-2, a third repeater 222-3, and a fourth repeater 222-4. The first to fourth repeaters 222-1, 222-2, 222-3, and 222-4 may each include a plurality of clock drivers or clock repeaters. The first repeater 222-1 may receive an output signal of the first switch 221-1 and may output the first distribution clock signal ICKD by repeating the output signal of the first switch 221-1. The second repeater 222-2 may receive an output signal of the second switch 221-2 and may output the second distribution clock signal QCKD by repeating the output signal of the second switch 221-2. The third repeater 222-3 may receive an output signal of the third switch 221-3 and may output the third distribution clock signal ICKBD by repeating the output signal of the third switch 221-3. The fourth repeater 222-4 may receive an output signal of the fourth switch 221-4 and may output the fourth distribution clock signal QCKBD by repeating the output signal of the fourth switch 221-4. The first to fourth repeaters 222-1, 222-2, 222-3, and 222-4 may distribute the first to fourth distribution clock signals ICKD, QCKD, ICKBD, and QCKBD to the first read clock transmission circuit 231, the second read clock transmission circuit 232, the first data transmission circuit 241, the second data transmission circuit 242, the third data transmission circuit 243, and the fourth data transmission circuit 244.

The first read clock transmission circuit 231 may receive the first to fourth distribution clock signals ICKD, QCKD, ICKBD, and QCKBD and may generate the first monitoring clock signal MCK1 in the monitoring mode. A delay time of the first read clock transmission circuit 231 may change based on the first delay control signal DC1. The first read clock transmission circuit 231 may further receive a phase selection signal PS. The first read clock transmission circuit 231 may generate the first monitoring clock signal MCK1 from one of the first to fourth distribution clock signals ICKD, QCKD, ICKBD, and QCKBD based on the phase selection signal PS. The second read clock transmission circuit 232 may receive the first to fourth distribution clock signals ICKD, QCKD, ICKBD, and QCKBD and may generate the second monitoring clock signal MCK2 in the monitoring mode. A delay time of the second read clock transmission circuit 232 may change based on the second delay control signal DC2. The second read clock transmission circuit 232 may further receive the phase selection signal PS. The second read clock transmission circuit 232 may generate the second monitoring clock signal MCK2 from one of the first to fourth distribution clock signals ICKD, QCKD, ICKBD, and QCKBD based on the phase selection signal PS.

The first data transmission circuit 241 may receive the first to fourth distribution clock signals ICKD, QCKD, ICKBD, and QCKBD and may generate the third monitoring clock signal MCK3 in the monitoring mode. A delay time of the first data transmission circuit 241 may change based on the third delay control signal DC3. The first data transmission circuit 241 may further receive the phase selection signal PS. The first data transmission circuit 241 may generate the third monitoring clock signal MCK3 from one of the first to fourth distribution clock signals ICKD, QCKD, ICKBD, and QCKBD based on the phase selection signal PS. The second data transmission circuit 242 may receive the first to fourth distribution clock signals ICKD, QCKD, ICKBD, and QCKBD and may generate the fourth monitoring clock signal MCK4 in the monitoring mode. A delay time of the second data transmission circuit 242 may change based on the fourth delay control signal DC4. The second data transmission circuit 242 may further receive the phase selection signal PS. The second data transmission circuit 242 may generate the fourth monitoring clock signal MCK4 from one of the first to fourth distribution clock signals ICKD, QCKD, ICKBD, and QCKBD based on the phase selection signal PS. The third data transmission circuit 243 may receive the first to fourth distribution clock signals ICKD, QCKD, ICKBD, and QCKBD and may generate the fifth monitoring clock signal MCK5 in the monitoring mode. A delay time of the third data transmission circuit 243 may change based on the fifth delay control signal DC5. The third data transmission circuit 243 may further receive the phase selection signal PS. The third data transmission circuit 243 may generate the fifth monitoring clock signal MCK5 from one of the first to fourth distribution clock signals ICKD, QCKD, ICKBD, and QCKBD based on the phase selection signal PS. The fourth data transmission circuit 244 may receive the first to fourth distribution clock signals ICKD, QCKD, ICKBD, and QCKBD and may generate the sixth monitoring clock signal MCK6 in the monitoring mode. A delay time of the fourth data transmission circuit 244 may change based on the sixth delay control signal DC6. The fourth data transmission circuit 244 may further receive the phase selection signal PS. The fourth data transmission circuit 244 may generate the sixth monitoring clock signal MCK6 from one of the first to fourth distribution clock signals ICKD, QCKD, ICKBD, and QCKBD based on the phase selection signal PS.

The delay monitoring circuit 250 may receive the first to sixth monitoring clock signals MCK1, MCK2, MCK3, MCK4, MCK5, and MCK6. The delay monitoring circuit 250 may form closed loops with the clock distribution network 220, the first and second read clock transmission circuits 231 and 232, and the first to fourth data transmission circuits 241, 242, 243, and 244 and may generate the oscillating signal ROD. The delay monitoring circuit 250 may form a first closed loop coupled to the switching circuit 221, the repeater circuit 222, and the first read clock transmission circuit 231 and may receive the first monitoring clock signal MCK1 and generate the first oscillating signal ROD1. The first oscillating signal ROD1 may be provided to the first read clock transmission circuit 231 through the switching circuit 221 and the repeater circuit 222. The first read clock transmission circuit 231 may generate the first monitoring clock signal MCK1 based on the first oscillating signal ROD1 and may provide the first monitoring clock signal MCK1 to the delay monitoring circuit 250. The delay monitoring circuit 250 may form a second closed loop coupled to the switching circuit 221, the repeater circuit 222, and the second read clock transmission circuit 232 and may receive the second monitoring clock signal MCK2 and generate the second oscillating signal ROD2. The second oscillating signal ROD2 may be provided to the second read clock transmission circuit 232 through the switching circuit 221 and the repeater circuit 222. The second read clock transmission circuit 232 may generate the second monitoring clock signal MCK2 based on the second oscillating signal ROD2 and may provide the second monitoring clock signal MCK2 to the delay monitoring circuit 250.

The delay monitoring circuit 250 may form a third closed loop coupled to the switching circuit 221, the repeater circuit 222, and the first data transmission circuit 241 and may receive the third monitoring clock signal MCK3 and generate the third oscillating signal ROD3. The third oscillating signal ROD3 may be provided to the first data transmission circuit 241 through the switching circuit 221 and the repeater circuit 222. The first data transmission circuit 241 may generate the third monitoring clock signal MCK3 based on the third oscillating signal ROD3 and may provide the third monitoring clock signal MCK3 to the delay monitoring circuit 250. The delay monitoring circuit 250 may form a fourth closed loop coupled to the switching circuit 221, the repeater circuit 222, and the second data transmission circuit 242 and may receive the fourth monitoring clock signal MCK4 and generate the fourth oscillating signal ROD4. The fourth oscillating signal ROD4 may be provided to the second data transmission circuit 242 through the switching circuit 221 and the repeater circuit 222. The second data transmission circuit 242 may generate the fourth monitoring clock signal MCK4 based on the fourth oscillating signal ROD4 and may provide the fourth monitoring clock signal MCK4 to the delay monitoring circuit 250. The delay monitoring circuit 250 may form a fifth closed loop coupled to the switching circuit 221, the repeater circuit 222, and the third data transmission circuit 243 and may receive the fifth monitoring clock signal MCK5 and generate the fifth oscillating signal ROD5. The fifth oscillating signal ROD5 may be provided to the third data transmission circuit 243 through the switching circuit 221 and the repeater circuit 222. The third data transmission circuit 243 may generate the fifth monitoring clock signal MCK5 based on the fifth oscillating signal ROD5 and may provide the fifth monitoring clock signal MCK5 to the delay monitoring circuit 250. The delay monitoring circuit 250 may form a sixth closed loop coupled to the switching circuit 221, the repeater circuit 222, and the fourth data transmission circuit 244 and may receive the sixth monitoring clock signal MCK6 and generate the sixth oscillating signal ROD6. The sixth oscillating signal ROD6 may be provided to the fourth data transmission circuit 244 through the switching circuit 221 and the repeater circuit 222. The fourth data transmission circuit 244 may generate the sixth monitoring clock signal MCK6 from the sixth oscillating signal ROD6 and may provide the sixth monitoring clock signal MCK6 to the delay monitoring circuit 250.

The delay monitoring circuit 250 may individually generate the first to sixth delay control signals DC1, DC2, DC3, DC4, DC5, and DC6 based on the first to sixth oscillating signals ROD1, ROD2, ROD3, ROD4, ROD5, and ROD6. The delay monitoring circuit 250 may further generate the phase selection signal PS based on the clock monitoring enable signal CMEN. For example, the phase selection signal PS may be a digital signal including multiple bits. When the clock monitoring enable signal CMEN is enabled, the delay monitoring circuit 250 may generate the phase selection signal PS having a first logic value. The phase selection signal PS having the first logic value may control the first distribution clock signal ICKD to be selected among the first to fourth distribution clock signals ICKD, QCKD, ICKBD, and QCKBD. After performing a monitoring operation on the first monitoring clock signal MCK1 and the first oscillating signal ROD1 generated from the first distribution clock signal ICKD, the delay monitoring circuit 250 may change the phase selection signal PS to have a second logic value. The phase selection signal PS having the second logic value may control the second distribution clock signal QCKD to be selected among the first to fourth distribution clock signals ICKD, QCKD, ICKBD, and QCKBD. After performing a monitoring operation on the second monitoring clock signal MCK2 and the first oscillating signal ROD1 generated from the second distribution clock signal QCKD, the delay monitoring circuit 250 may change the phase selection signal PS to have a third logic value. The phase selection signal PS having the third logic value may control the third distribution clock signal ICKBD to be selected among the first to fourth distribution clock signals ICKD, QCKD, ICKBD, and QCKBD. After performing a monitoring operation on the third monitoring clock signal MCK3 and the first oscillating signal ROD1 generated from the third distribution clock signal ICKBD, the delay monitoring circuit 250 may change the phase selection signal PS to have a fourth logic value. The phase selection signal PS having the fourth logic value may control the fourth distribution clock signal QCKBD to be selected among the first to fourth distribution clock signals ICKD, QCKD, ICKBD, and QCKBD. After performing a monitoring operation on the fourth monitoring clock signal MCK4 and the first oscillating signal ROD1 generated from the fourth distribution clock signal QCKBD, the delay monitoring circuit 250 may again change the phase selection signal PS to have the first logic value. After the monitoring operations on the first oscillating signal ROD1 generated based on each of the first to fourth distribution clock signals ICKD, QCKD, ICKBD, and QCKBD have been performed, the delay monitoring circuit 250 may perform monitoring operations on the second to sixth oscillating signals ROD2, ROD3, ROD4, ROD5, and ROD6. The delay monitoring circuit 250 may form a total of twenty-four closed loops with the clock distribution network 220, the first and second read clock transmission circuits 231 and 232, and the first to fourth data transmission circuits 241, 242, 243, and 244 while changing the logic value of the phase selection signal PS and may monitor the oscillating signals generated through the twenty-four closed loops. The order of the monitoring operations is not limited, and the sequence of the monitoring operations may be modified and/or changed in various ways. For example, the delay monitoring circuit 250 may set the phase selection signal PS to a first logic value, then perform monitoring operations on the first to sixth oscillating signals ROD1, ROD2, ROD3, ROD4, ROD5, and ROD6, and then change the phase selection signal PS to a second logic value.

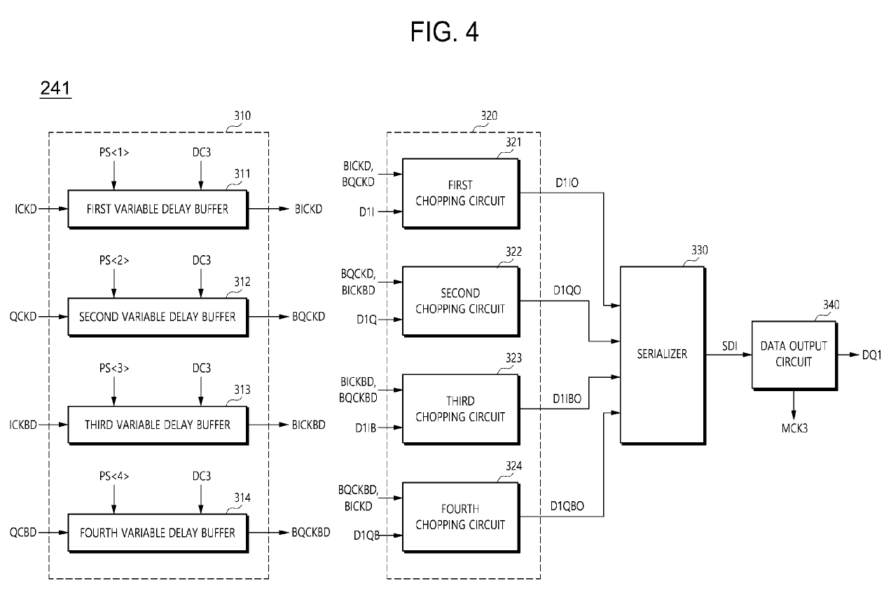

FIG. 4 is a diagram showing a configuration of the first data transmission circuit 241 according to an embodiment of the present disclosure. Referring to FIG. 4, the first data transmission circuit 241 may include a variable delay buffer circuit 310, a data chopping circuit 320, a serializer 330, and a data output circuit 340. The variable delay buffer circuit 310 may receive the first to fourth distribution clock signals ICKD, QCKD, ICKBD, and QCKBD, the phase selection signal PS, and the third delay control signal DC3 and may generate a first buffered clock signal BICKD, a second buffered clock signal BQCKD, a third buffered clock signal BICKBD, and a fourth buffered clock signal BQCKBD. The variable delay buffer circuit 310 may include a first variable delay buffer 311, a second variable delay buffer 312, a third variable delay buffer 313, and a fourth variable delay buffer 314. For example, the phase selection signal PS may include four bits. The first variable delay buffer 311 may buffer the first distribution clock signal ICKD based on a first bit PS<1> of the phase selection signal and the third delay control signal DC3 and may generate the first buffered clock signal BICKD. The first variable delay buffer 311 may be activated when the first bit PS<1> of the phase selection signal is at a high logic level and may buffer the first distribution clock signal ICKD. A delay time of the first variable delay buffer 311 may be changed based on the third delay control signal DC3. The first variable delay buffer 311 may change a timing at which the first buffered clock signal BICKD is output based on the third delay control signal DC3. For example, as a value of the third delay control signal DC3 increases, a delay time of the first variable delay buffer 311 may increase and a timing at which the first buffered clock signal BICKD is output may be delayed. As the value of the third delay control signal DC3 decreases, the delay time of the first variable delay buffer 311 may decrease and the timing at which the first buffered clock signal BICKD is output may be advanced and/or relatively earlier.

The second variable delay buffer 312 may buffer the second distribution clock signal QCKD based on a second bit PS<2> of the phase selection signal and the third delay control signal DC3 and may generate the second buffered clock signal BQCKD. The second variable delay buffer 312 may be activated when the second bit PS<2> of the phase selection signal is at a high logic level and may buffer the second distribution clock signal QCKD. A delay time of the second variable delay buffer 312 may be changed based on the third delay control signal DC3. The second variable delay buffer 312 may change a timing at which the second buffered clock signal BQCKD is output based on the third delay control signal DC3. The third variable delay buffer 313 may buffer the third distribution clock signal ICKBD based on a third bit PS<3> of the phase selection signal and the third delay control signal DC3 and may generate the third buffered clock signal BICKBD. The third variable delay buffer 313 may be activated when the third bit PS<3> of the phase selection signal is at a high logic level and may buffer the third distribution clock signal ICKBD. A delay time of the third variable delay buffer 313 may be changed based on the third delay control signal DC3. The third variable delay buffer 313 may change a timing at which the third buffered clock signal BICKBD is output based on the third delay control signal DC3. The fourth variable delay buffer 314 may buffer the fourth distribution clock signal QCKBD based on a fourth bit PS<4> of the phase selection signal and the third delay control signal DC3 and may generate the fourth buffered clock signal BQCKBD. The fourth variable delay buffer 314 may be activated when the fourth bit PS<4> of the phase selection signal is at a high logic level and may buffer the fourth distribution clock signal QCKBD. A delay time of the fourth variable delay buffer 314 may be changed based on the third delay control signal DC3. The fourth variable delay buffer 314 may change a timing at which the fourth buffered clock signal BQCKBD is output based on the third delay control signal DC3. In an embodiment, the first to fourth variable delay buffers 311, 312, 313, and 314 may be modified to receive delay control signals having different values. The delay monitoring circuit 250 shown in FIG. 3 may provide different delay control signals to the first to fourth variable delay buffers 311, 312, 313, and 314 to individually control delay times of the first to fourth variable delay buffers 311, 312, 313, and 314.

The data chopping circuit 320 may receive the first to fourth buffered clock signals BICKD, BQCKD, BICKBD, and BQCKBD and first internal data D1 and may generate first to fourth synchronized data signals D1IO, D1QO, D1IBO, and D1QBO based on the first to fourth buffered clock signals BICKD, BQCKD, BICKBD, and BQCKBD and the first internal data D1. The first internal data D1 may include first to fourth output data signals D1I, D1Q, D1IB, and DbQB. The data chopping circuit 320 may generate the first to fourth synchronized data signals D1IO, D1QO, D1IBO, and D1QBO by synchronizing the first to fourth output data signals D1I, D1Q, D1IB, and D1QB with the first to fourth buffered clock signals BICKD, BQCKD, BICKBD, and BQCKBD.

The data chopping circuit 320 may include a first chopping circuit 321, a second chopping circuit 322, a third chopping circuit 323, and a fourth chopping circuit 324. The first chopping circuit 321 may receive the first and second buffered clock signals BICKD and BQCKD and the first output data signal D1I. The first chopping circuit 321 may generate the first synchronized data signal D1IO from the first output data signal D1I in synchronization with the first and second buffered clock signals BICKD and BQCKD. The first chopping circuit 321 may generate the first synchronized data signal D1IO having a logic level corresponding to the first output data signal D1I when the first buffered clock signal BICKD is at a high logic level and the second buffered clock signal BQCKD is at a low logic level. For example, the first output data signal D1I may have a valid window corresponding to one period of the first distribution clock signal ICKD or the first buffered clock signal BICKD. A portion of time from a rising edge of the first buffered clock signal BICKD to a rising edge of the second buffered clock signal BQCKD may be the valid window of the first output data signal D1I. The first synchronized data signal D1IO may have a valid window corresponding to a portion of time from the rising edge of the first buffered clock signal BICKD to the rising edge of the second buffered clock signal BQCKD.

The second chopping circuit 322 may receive the second and third buffered clock signals BQCKD and BICKBD and the second output data signal D1Q. The second chopping circuit 322 may generate the second synchronized data signal D1QO from the second output data signal D1Q in synchronization with the second and third buffered clock signals BQCKD and BICKBD. The second chopping circuit 322 may generate the second synchronized data signal D1QO having a logic level corresponding to the second output data signal D1Q when the second buffered clock signal BQCKD is at a high logic level and the third buffered clock signal BICKBD is at a low logic level. The third chopping circuit 323 may receive the third and fourth buffered clock signals BICKBD and BQCKBD and the third output data signal D1IB. The third chopping circuit 323 may generate the third synchronized data signal D1IBO from the third output data signal D1IB in synchronization with the third and fourth buffered clock signals BICKBD and BQCKBD. The third chopping circuit 323 may generate the third synchronized data signal D1IBO having a logic level corresponding to the third output data signal D1IB when the third buffered clock signal BICKBD is at a high logic level and the fourth buffered clock signal BQCKBD is at a low logic level. The fourth chopping circuit 324 may receive the fourth and first buffered clock signals BQCKBD and BICKD and the fourth output data signal D1QB. The fourth chopping circuit 324 may generate the fourth synchronized data signal D1QBO from the fourth output data signal D1QB in synchronization with the fourth and first buffered clock signals BQCKBD and BICKD. The fourth chopping circuit 324 may generate the fourth synchronized data signal D1QBO having a logic level corresponding to the fourth output data signal D1QB when the fourth buffered clock signal BQCKBD is at a high logic level and the first buffered clock signal BICKD is at a low logic level.

The serializer 330 may receive the first to fourth synchronized data signals D1IO, D1QO, D1IBO, and D1QBO from the data chopping circuit 320. The serializer 330 may serialize the first to fourth synchronized data signals D1IO, D1QO, D1IBO, and D1QBO to generate a serialized data signal SDI. The serializer 330 may sequentially output the first to fourth synchronized data signals D1IO, D1QO, D1IBO, and D1QBO as bits of the serialized data signal SDI. For example, the serializer 330 may output the first synchronized data signal D1IO as an n-th bit of the serialized data signal SDI, the second synchronized data signal D1QO as an (n+1)-th bit of the serialized data signal SDI, the third synchronized data signal D1IBO as an (n+2)-th bit of the serialized data signal SDI, and the fourth synchronized data signal D1QBO as an (n+3)-th bit of the serialized data signal SDI. Here, n may be an integer equal to or greater than 1. In an embodiment, the serializer 330 may include a combination of a 4:2 serializer and a 2:1 serializer. The data output circuit 340 may receive the serialized data signal SDI from the serializer 330 and may generate the first data DQ1 and the third monitoring clock signal MCK3 based on the serialized data signal SDI. The data output circuit 340 may change logic levels of the first data DQ1 and the third monitoring clock signal MCK3 according to a logic level of the serialized data signal SDI.

The second to fourth data transmission circuits 242, 243, and 244 may include substantially the same configuration as the first data transmission circuit 241, shown in FIG. 4, except that they respectively receive the fourth to sixth delay control signals DC4, DC5, and DC6 instead of the third delay control signal DC3, receive the second to fourth internal data D2, D3, and D4 instead of the first internal data D1, output the second to fourth data DQ2, DQ3, and DQ4 instead of the first data DQ1, and output the fourth to sixth monitoring clock signals MCK4, MCK5, and MCK6 instead of the third monitoring clock signal MCK3. The first and second read clock transmission circuits 231 and 232 may also include substantially the same configuration as the first data transmission circuit 241, shown in FIG. 4, except that they respectively receive the first and second delay control signals DC1 and DC2 instead of the third delay control signal DC3, receive the first and second dummy data DM1 and DM2 instead of the first internal data D1, output the first and second read clock signals RCK and RCKB instead of the first data DQ1, and output the first and second monitoring clock signals MCK1 and MCK2 instead of the third monitoring clock signal MCK3.

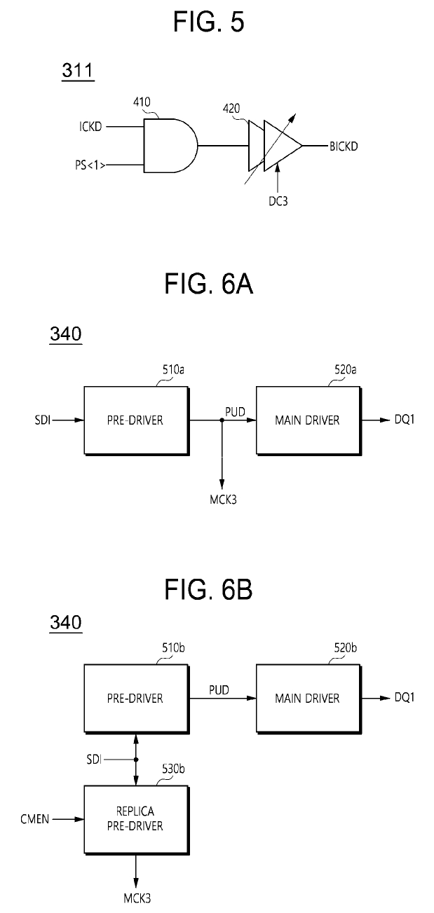

FIG. 5 is a diagram showing a configuration of the first variable delay buffer 311 shown in FIG. 4. Referring to FIG. 5, the first variable delay buffer 311 may include an AND gate 410 and a delay circuit 420. The AND gate 410 may receive the first distribution clock signal ICKD and a first bit PS<1> of the phase selection signal. The delay circuit 420 may receive an output signal of the AND gate 410 and may delay the output signal of the AND gate 410 to output the first buffered clock signal BICKD. The delay circuit 420 may receive the third delay control signal DC3 and may change a delay time of the delay circuit 420 based on the third delay control signal DC3. In an embodiment, the third delay control signal DC3 may be a digital signal including a plurality of bits, and the delay circuit 420 may change the delay time by adjusting the number of drivers turned on based on the third delay control signal DC3. In an embodiment, the third delay control signal DC3 may be an analog signal having various voltage levels, and the delay circuit 420 may change the delay time by adjusting a driving current of the drivers based on the third delay control signal DC3.

FIG. 6A is a diagram showing a configuration of the data output circuit 340 shown in FIG. 4. Referring to FIG. 6A, the data output circuit 340 may include a pre-driver 510a and a main driver 520a. The pre-driver 510a may receive the serialized data signal SDI and may generate an up-down driving signal PUD based on the serialized data signal SDI. The up-down driving signal PUD may have a logic level that changes according to a logic level of the serialized data signal SDI. The up-down driving signal PUD may serve as a signal for driving the main driver 520a and may include a pull-up driving signal and a pull-down driving signal. The up-down driving signal PUD may be provided as the third monitoring clock signal MCK3. The main driver 520a may drive a data transmission line of the data bus 104, on which the first data DQ1 is transmitted, based on the up-down driving signal PUD and may output the first data DQ1. The main driver 520a may perform pull-up driving on the data transmission line based on the up-down driving signal PUD to drive the first data DQ1 to a high logic level or may perform pull-down driving on the data transmission line to drive the first data DQ1 to a low logic level.

FIG. 6B is a diagram showing a configuration of the data output circuit 340 shown in FIG. 4. The data output circuit 340 may include a pre-driver 510b, a replica pre-driver 530b, and a main driver 520b. The pre-driver 510b may receive the serialized data signal SDI and may generate an up-down driving signal PUD based on the serialized data signal SDI. The up-down driving signal PUD may have a logic level that changes according to a logic level of the serialized data signal SDI and may include a pull-up driving signal and a pull-down driving signal as signals for driving the main driver 520b. The replica pre-driver 530b may have substantially the same structure as the pre-driver 510b. The replica pre-driver 530b may receive the clock monitoring enable signal CMEN and the serialized data signal SDI and may generate the third monitoring clock signal MCK3. The replica pre-driver 530b may be activated when the clock monitoring enable signal CMEN is enabled. When the clock monitoring enable signal CMEN is enabled, the replica pre-driver 530b may generate the third monitoring clock signal MCK3 based on the serialized data signal SDI. The replica pre-driver 530b may generate the third monitoring clock signal MCK3 through a path separate from that of the pre-driver 510b, such that it might not affect operations of the pre-driver 510b and the main driver 520b operating in the normal mode. The main driver 520b may drive a data transmission line of the data bus 104, on which the first data DQ1 is transmitted, based on the up-down driving signal PUD and may output the first data DQ1. The main driver 520b may perform pull-up driving on the data transmission line to drive the first data DQ1 to a high logic level or may perform pull-down driving on the data transmission line to drive the first data DQ1 to a low logic level based on the up-down driving signal PUD.

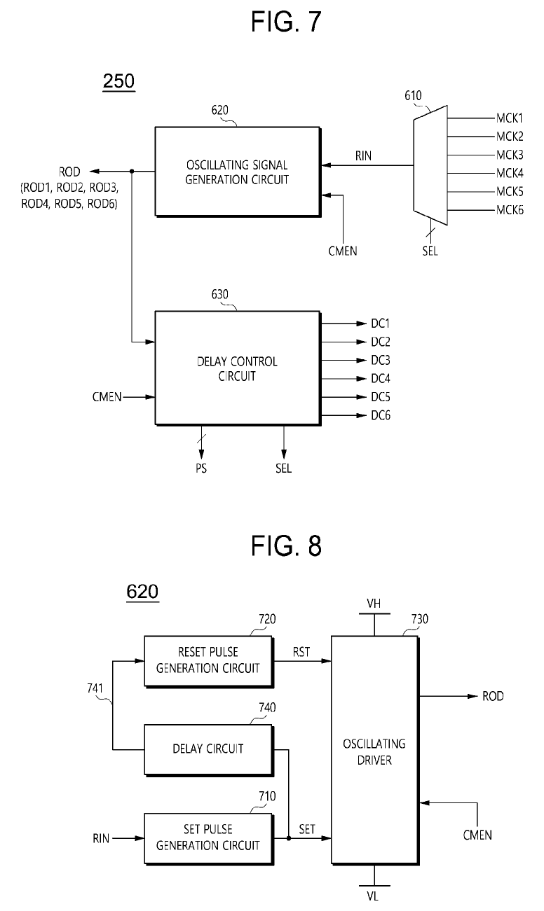

FIG. 7 is a diagram showing a configuration of the delay monitoring circuit 250 according to an embodiment of the present disclosure. Referring to FIG. 7, the delay monitoring circuit 250 may include a selection circuit 610, an oscillating signal generation circuit 620, and a delay control circuit 630. The selection circuit 610 may receive the first to sixth monitoring clock signals MCK1, MCK2, MCK3, MCK4, MCK5, and MCK6, and a selection signal SEL. The selection circuit 610 may output one of the first to sixth monitoring clock signals MCK1, MCK2, MCK3, MCK4, MCK5, and MCK6 as an oscillating input signal RIN based on the selection signal SEL. The selection circuit 610 may be implemented as a 6:1 multiplexer. The oscillating signal generation circuit 620 may receive the oscillating input signal RIN and the clock monitoring enable signal CMEN. The oscillating signal generation circuit 620 may generate the oscillating signal ROD based on the oscillating input signal RIN and the clock monitoring enable signal CMEN. The oscillating signal generation circuit 620 may generate the first oscillating signal ROD1 when the first monitoring clock signal MCK1 is output as the oscillating input signal RIN. The oscillating signal generation circuit 620 may generate the second oscillating signal ROD2 when the second monitoring clock signal MCK2 is output as the oscillating input signal RIN. The oscillating signal generation circuit 620 may generate the third oscillating signal ROD3 when the third monitoring clock signal MCK3 is output as the oscillating input signal RIN. The oscillating signal generation circuit 620 may generate the fourth oscillating signal ROD4 when the fourth monitoring clock signal MCK4 is output as the oscillating input signal RIN. The oscillating signal generation circuit 620 may generate the fifth oscillating signal ROD5 when the fifth monitoring clock signal MCK5 is output as the oscillating input signal RIN. The oscillating signal generation circuit 620 may generate the sixth oscillating signal ROD6 when the sixth monitoring clock signal MCK6 is output as the oscillating input signal RIN. The oscillating signal generation circuit 620 may change a logic level of the oscillating signal ROD in synchronization with only one edge of the oscillating input signal RIN, which is either a rising edge or a falling edge, so that phase skews among the first to sixth oscillating signals ROD1, ROD2, ROD3, ROD4, ROD5, and ROD6 can be accurately monitored. For example, the oscillating signal generation circuit 620 may change a logic level of the oscillating signal ROD in synchronization with only a rising edge of the oscillating input signal RIN.

The delay control circuit 630 may receive the oscillating signal ROD and may generate the first to sixth delay control signals DC1, DC2, DC3, DC4, DC5, and DC6. The delay control circuit 630 may monitor a period of the oscillating signal ROD by counting rising edges of the oscillating signal ROD and may detect phase skews among the first to sixth oscillating signals ROD1, ROD2, ROD3, ROD4, ROD5, and ROD6. The delay control circuit 630 may generate a first count value by counting rising edges of the first oscillating signal ROD1, a second count value by counting rising edges of the second oscillating signal ROD2, a third count value by counting rising edges of the third oscillating signal ROD3, a fourth count value by counting rising edges of the fourth oscillating signal ROD4, a fifth count value by counting rising edges of the fifth oscillating signal ROD5, and a sixth count value by counting rising edges of the sixth oscillating signal ROD6. When the first to sixth oscillating signals ROD1, ROD2, ROD3, ROD4, ROD5, and ROD6 are counted for a time, differences may occur in the first to sixth count values according to the periods of the oscillating signals ROD1, ROD2, ROD3, ROD4, ROD5, and ROD6. The delay control circuit 630 may generate the first to sixth delay control signals DC1, DC2, DC3, DC4, DC5, and DC6 based on the first to sixth count values. The delay control circuit 630 may also generate the phase selection signal PS and the selection signal SEL based on the clock monitoring enable signal CMEN and may generate monitoring results of the first to sixth oscillating signals ROD1, ROD2, ROD3, ROD4, ROD5, and ROD6.

FIG. 8 is a diagram showing a configuration of the oscillating signal generation circuit 620 according to an embodiment of the present disclosure. Referring to FIG. 8, the oscillating signal generation circuit 620 may be activated when the clock monitoring enable signal CMEN is enabled and may transition the oscillating signal ROD to a first logic level based on the clock monitoring enable signal CMEN. The oscillating signal generation circuit 620 may generate a set pulse signal SET based on the oscillating input signal RIN and may transition the oscillating signal ROD from the first logic level to a second logic level based on the set pulse signal SET. The oscillating signal generation circuit 620 may generate a reset pulse signal RST based on the set pulse signal SET. The oscillating signal generation circuit 620 may generate the reset pulse signal RST by delaying the set pulse signal SET. The oscillating signal generation circuit 620 may transition the oscillating signal ROD from the second logic level to the first logic level based on the reset pulse signal RST.

The oscillating signal generation circuit 620 may include a set pulse generation circuit 710, a reset pulse generation circuit 720, and an oscillating driver 730. The set pulse generation circuit 710 may receive the oscillating input signal RIN and may generate the set pulse signal SET based on the oscillating input signal RIN. The set pulse generation circuit 710 may generate the set pulse signal SET, synchronized with a rising edge of the oscillating signal ROD, based on the oscillating input signal RIN. For example, the set pulse generation circuit 710 may receive the oscillating input signal RIN and may generate the set pulse signal SET based on a rising edge of the oscillating input signal RIN. The reset pulse generation circuit 720 may receive the set pulse signal SET from the set pulse generation circuit 710. The reset pulse generation circuit 720 may generate the reset pulse signal RST based on the set pulse signal SET. The reset pulse generation circuit 720 may enable the reset pulse signal RST in synchronization with a time point at which the set pulse signal SET is disabled. The oscillating signal generation circuit 620 may further include a delay circuit 740. The delay circuit 740 may delay the set pulse signal SET. The reset pulse generation circuit 720 may receive a delayed set pulse signal 741 from the delay circuit 740 and may generate the reset pulse signal RST based on the delayed set pulse signal 741. The delay circuit 740 may be provided to adjust a timing at which the reset pulse signal RST is generated. A delay time of the delay circuit 740 may be arbitrarily set and may be changed in various ways.

The oscillating driver 730 may receive the clock monitoring enable signal CMEN, the set pulse signal SET, and the reset pulse signal RST and may generate the oscillating signal ROD based on the clock monitoring enable signal CMEN, the set pulse signal SET, and the reset pulse signal RST. The oscillating driver 730 may be activated when the clock monitoring enable signal CMEN is enabled. The oscillating driver 730 may transition the oscillating signal ROD from a second logic level to a first logic level and may change a logic level of the oscillating signal ROD according to the set pulse signal SET and the reset pulse signal RST. When the clock monitoring enable signal CMEN is disabled, the oscillating driver 730 may be deactivated, and the oscillating signal ROD may be fixed at the second logic level. The oscillating driver 730 may drive the oscillating signal ROD to the second logic level based on the set pulse signal SET and may drive the oscillating signal ROD to the first logic level based on the reset pulse signal RST. The oscillating driver 730 may transition the oscillating signal ROD from the first logic level to the second logic level when the set pulse signal SET is enabled and may transition the oscillating signal ROD from the second logic level to the first logic level when the reset pulse signal RST is enabled. The oscillating driver 730 may receive a first power supply voltage VH and a second power supply voltage VL and may generate the oscillating signal ROD based on the first power supply voltage VH and the second power supply voltage VL. The first power supply voltage VH may have a higher voltage level than the second power supply voltage VL. The oscillating driver 730 may drive the oscillating signal ROD to a voltage level of the second power supply voltage VL based on the set pulse signal SET and may drive the oscillating signal ROD to a voltage level of the first power supply voltage VH based on the reset pulse signal RST.

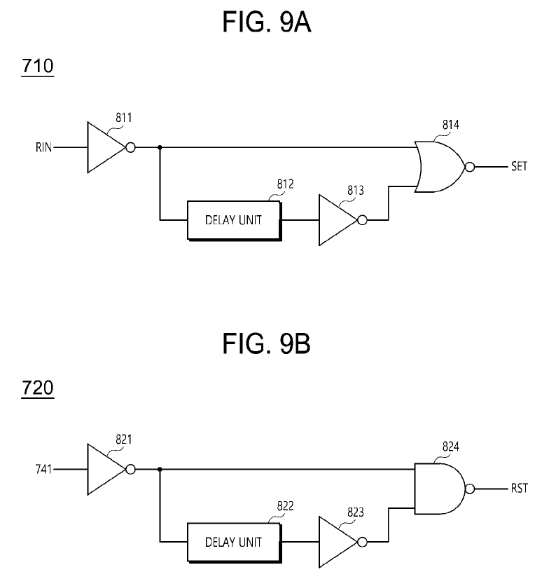

FIG. 9A is a diagram showing a configuration of the set pulse generation circuit 710 shown in FIG. 8. Referring to FIG. 9A, the set pulse generation circuit 710 may include a first inverter 811, a delay unit 812, a second inverter 813, and a NOR gate 814. The first inverter 811 may receive the oscillating input signal RIN and may invert and drive the oscillating input signal RIN. The delay unit 812 may receive an output of the first inverter 811 and may delay the output of the first inverter 811. A delay amount of the delay unit 812 may determine a pulse width of the set pulse signal SET. The second inverter 813 may receive an output of the delay unit 812 and may invert and drive the output of the delay unit 812. The NOR gate 814 may receive the output of the first inverter 811 and an output of the second inverter 813 and may output the set pulse signal SET. The set pulse generation circuit 710 may generate the set pulse signal SET as a high logic level pulse signal having a pulse width corresponding to a delay amount of the delay unit 812 when the oscillating input signal RIN transitions from a low logic level to a high logic level.

FIG. 9B is a diagram showing a configuration of the reset pulse generation circuit 720 shown in FIG. 8. Referring to FIG. 9B, the reset pulse generation circuit 720 may include a first inverter 821, a delay unit 822, a second inverter 823, and a NAND gate 824. The first inverter 821 may receive the delayed set pulse signal 741 and may invert the delayed set pulse signal 741. When the oscillating signal generation circuit 620 does not include the delay circuit 740, the first inverter 821 may receive the set pulse signal SET and may invert the set pulse signal SET. The delay unit 822 may receive an output of the first inverter 821 and may delay the output of the first inverter 821. A delay amount of the delay unit 822 may determine a pulse width of the reset pulse signal RST. The second inverter 823 may receive an output of the delay unit 822 and may invert the output of the delay unit 822. The NAND gate 824 may receive the output of the first inverter 821 and an output of the second inverter 823 and may output the reset pulse signal RST. The reset pulse generation circuit 720 may generate the reset pulse signal RST as a low logic level pulse signal having a pulse width corresponding to a delay amount of the delay unit 822 when the set pulse signal SET or the delayed set pulse signal 741 transitions from a high logic level to a low logic level.

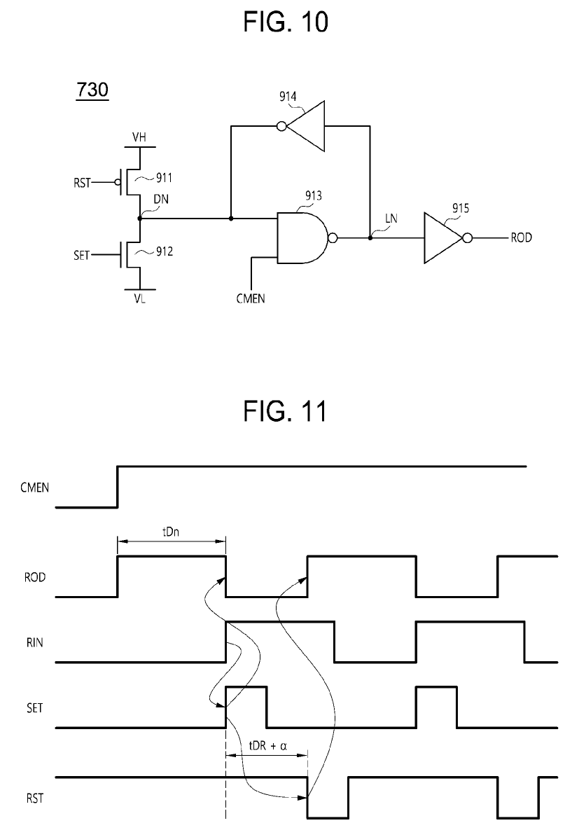

FIG. 10 is a diagram showing a configuration of the oscillating driver 730 shown in FIG. 8. Referring to FIG. 10, the oscillating driver 730 may include a pull-up transistor 911, a pull-down transistor 912, a NAND gate 913, a first inverter 914, and a second inverter 915. The pull-up transistor 911 may drive a driving node DN with a first power supply voltage VH based on the reset pulse signal RST. The pull-up transistor 911 may be a P-channel MOS transistor. In an embodiment, the pull-up transistor 911 may also be implemented as an N-channel MOS transistor. A source of the pull-up transistor 911 may receive the first power supply voltage VH, and a drain thereof may be coupled to the driving node DN. A gate of the pull-up transistor 911 may receive the reset pulse signal RST. The pull-up transistor 911 may drive the driving node DN with the first power supply voltage VH when the reset pulse signal RST is enabled at a low logic level. The pull-down transistor 912 may drive the driving node DN with the second power supply voltage VL based on the set pulse signal SET. The pull-down transistor 912 may be an N-channel MOS transistor. A drain of the pull-down transistor 912 may be coupled to the driving node DN, and a source thereof may receive the second power supply voltage VL. A gate of the pull-down transistor 912 may receive the set pulse signal SET. The pull-down transistor 912 may drive the driving node DN with the second power supply voltage VL when the set pulse signal SET is enabled at a high logic level. The NAND gate 913 may be coupled to the driving node DN and may receive a signal of the driving node DN. The NAND gate 913 may receive the signal of the driving node DN and the clock monitoring enable signal CMEN. The NAND gate 913 may invert and drive the signal of the driving node DN when the clock monitoring enable signal CMEN is enabled at a high logic level. An output of the NAND gate 913 may be coupled to a latch node LN. The first inverter 914 may be coupled between the latch node LN and the driving node DN. The first inverter 914 may invert and drive a signal of the latch node LN and may output the inverted signal to the driving node DN. The first inverter 914, together with the NAND gate 913, may form an inverted latch to maintain logic levels of the driving node DN and the latch node LN. The second inverter 915 may receive the signal of the latch node LN and may invert and drive the signal of the latch node LN to output the oscillating signal ROD.

FIG. 11 is a diagram illustrating an operation of the oscillating signal generation circuit 620 according to an embodiment of the present disclosure. With reference to FIGS. 8-11, the operation of the oscillating signal generation circuit 620 according to an embodiment of the present disclosure is described as follows. When the clock monitoring signal CMEN is enabled, the oscillating signal ROD may transition from a low logic level to a high logic level. The oscillating signal ROD may be delayed for a variable delay time tDn and provided as the oscillating input signal RIN. The variable delay time tDn may correspond to any one of the first to sixth propagation delays. For example, referring also to FIG. 3, when the delay monitoring circuit 250 forms the first closed loop with the clock distribution network 220 and the first read clock transmission circuit 231, the first monitoring clock signal MCK1 may be transmitted as the oscillating input signal RIN, and the variable delay time tDn may correspond to the first propagation delay. The set pulse generation circuit 710 may generate the set pulse signal SET enabled to a high logic level in synchronization with a rising edge of the oscillating input signal RIN. When the set pulse signal SET is enabled, the oscillating driver 730 may transition the oscillating signal ROD from a high logic level to a low logic level. The delay circuit 740 may delay the set pulse signal SET by a reference delay time tDR and may transmit the delayed set pulse signal 741 to the reset pulse generation circuit 720. The reset pulse generation circuit 720 may enable the reset pulse signal RST to a low logic level after the reference delay time tDR and a delay time α of the delay unit 822 have elapsed from the time when the set pulse signal SET is enabled. When the reset pulse signal RST is enabled, the oscillating driver 730 may transition the oscillating signal ROD from a low logic level to a high logic level. A high-level interval of the oscillating signal ROD may correspond to the variable delay time tDn, and a low-level interval of the oscillating signal ROD may correspond to the sum of the reference delay time tDR and the delay time α of the delay unit 822. The oscillating signal ROD may have a high-level interval that changes according to the propagation delay, while maintaining a low-level interval that is constant regardless of the propagation delay. Accordingly, a period of the oscillating signal ROD may change only in accordance with the propagation delay.

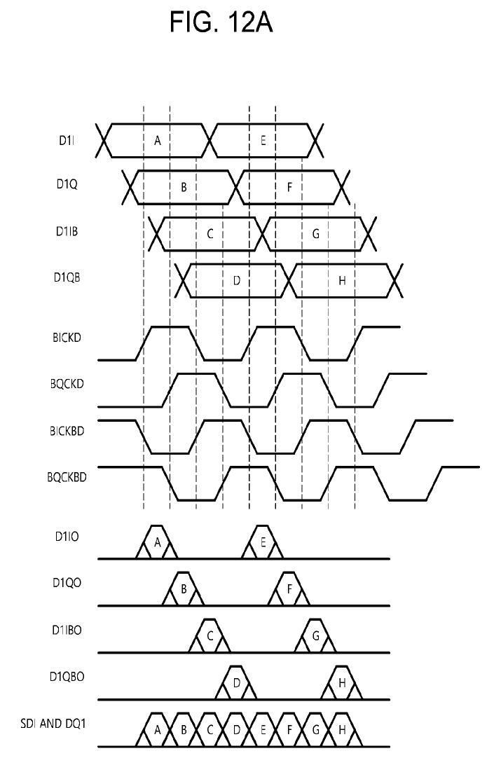

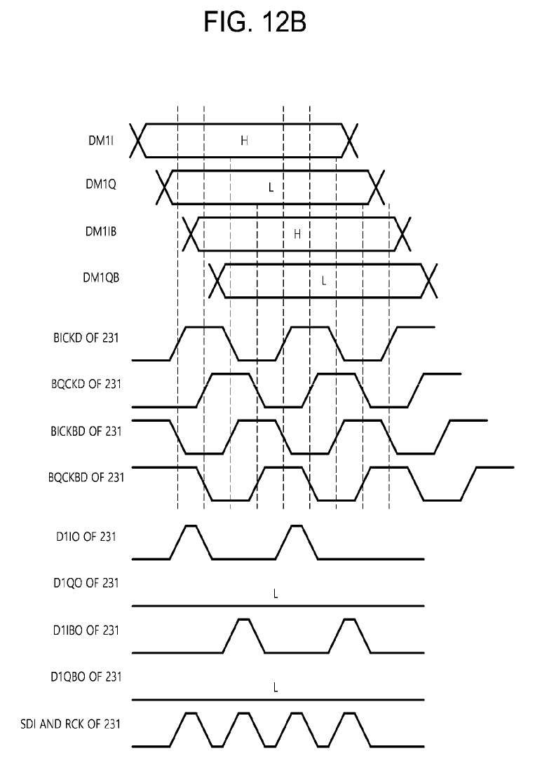

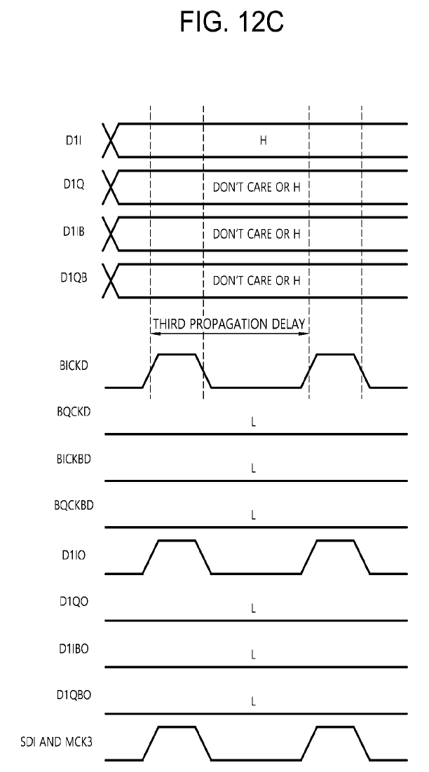

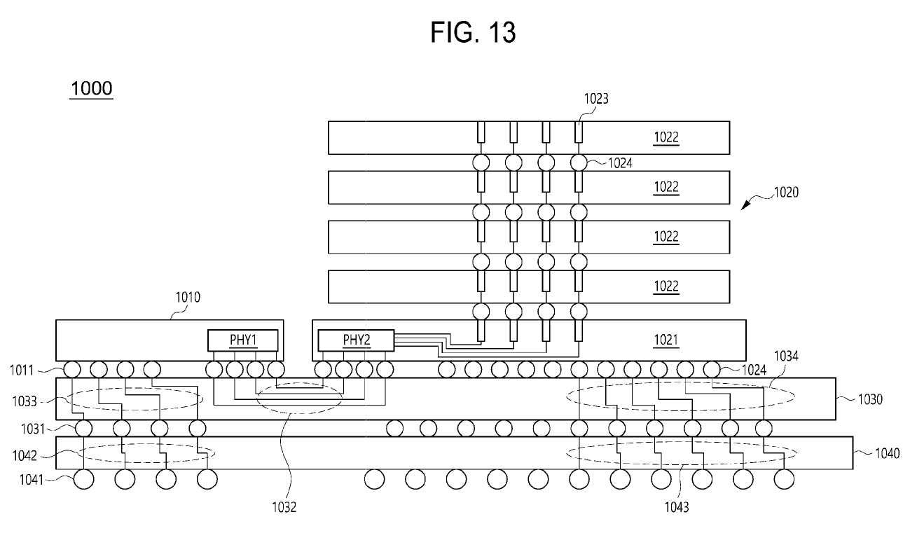

FIGS. 12A-12C are timing diagrams showing operations of the semiconductor apparatus 200 according to an embodiment of the present disclosure. With reference to FIGS. 12A-12C, the operation of the semiconductor apparatus 200 according to an embodiment of the present disclosure is described as follows. FIG. 12A is a timing diagram illustrating an operation of the first data transmission circuit 241 when the semiconductor apparatus 200 operates in the normal mode. The clock receiving circuit 210 of the semiconductor apparatus 200 may receive the first and second write clock signals WCK and WCKB and may generate the first to fourth internal clock signals ICK, QCK, ICKB, and QCKB. The clock distribution network 220 may distribute the first to fourth internal clock signals ICK, QCK, ICKB, and QCKB as the first to fourth distribution clock signals ICKD, QCKD, ICKBD, and QCKBD, respectively. The first data transmission circuit 241 may receive the first to fourth distribution clock signals ICKD, QCKD, ICKBD, and QCKBD and the first internal data D1. The first data transmission circuit 241 may generate the first to fourth synchronized data signals D1IO, D1QO, D1IBO, and D1QBO from the first to fourth output data signals D1I, D1Q, D1IB, and D1QB in synchronization with the first to fourth distribution clock signals ICKD, QCKD, ICKBD, and QCKBD. The first data transmission circuit 241 may generate a first bit A and a second bit E of the first synchronized data signal D1IO having logic levels corresponding to logic levels of a first bit A and a second bit E of the first output data signal D1I, during a portion of time in which the first buffered clock signal BICKD is at a high logic level and the second buffered clock signal BQCKD is at a low logic level. The first data transmission circuit 241 may generate a first bit B and a second bit F of the second synchronized data signal D1QO having logic levels corresponding to logic levels of a first bit B and a second bit F of the second output data signal D1Q, during a portion of time in which the second buffered clock signal BQCKD is at a high logic level and the third buffered clock signal BICKBD is at a low logic level. The first data transmission circuit 241 may generate a first bit C and a second bit G of the third synchronized data signal D1IBO having logic levels corresponding to logic levels of a first bit C and a second bit G of the third output data signal D1IB, during a portion of time in which the third buffered clock signal BICKBD is at a high logic level and the fourth buffered clock signal BQCKBD is at a low logic level. The first data transmission circuit 241 may generate a first bit D and a second bit H of the fourth synchronized data signal D1QBO having logic levels corresponding to logic levels of a first bit D and a second bit H of the fourth output data signal D1QB, during a portion of time in which the fourth buffered clock signal BQCKBD is at a high logic level and the first buffered clock signal BICKD is at a low logic level. The first data transmission circuit 241 may serialize the first and second bits of the first to fourth synchronized data signals D1IO, D1QO, D1IBO, and D1QBO and may sequentially output them as the serial data signal SDI in the order of the first bit A of the first synchronized data signal D1IO, the first bit B of the second synchronized data signal D1QO, the first bit C of the third synchronized data signal D1IBO, the first bit D of the fourth synchronized data signal D1QBO, the second bit E of the first synchronized data signal D1IO, the second bit F of the second synchronized data signal D1QO, the second bit G of the third synchronized data signal D1IBO, and the second bit H of the fourth synchronized data signal D1QBO. The first data transmission circuit 241 may output the first data DQ1 having a logic level corresponding to a logic level of the serial data signal SDI. The second to fourth data transmission circuits 242, 243, and 244 may operate in substantially the same manner as the first data transmission circuit 241.

FIG. 12B is a timing diagram illustrating an operation of the first read clock transmission circuit 231 when the semiconductor apparatus 200 operates in the normal mode. The first read clock transmission circuit 231 may receive the first dummy data DM1, and the first dummy data DM1 may include first to fourth dummy data signals DM1I, DM1Q, DM1IB, and DM1QB. The first and third dummy data signals DM1I and DM1IB may be fixed to a high logic level, and the second and fourth dummy data signals DM1Q and DM1QB may be fixed to a low logic level. Accordingly, the first read clock transmission circuit 231 may output the first synchronized data signal DM1IO with a high logic level pulse during a portion of time in which the first buffered clock signal BICKD is at a high logic level and the second buffered clock signal BQCKD is at a low logic level and may output the third synchronized data signal DM1IBO with a high logic level pulse during a portion of time in which the third buffered clock signal BICKBD is at a high logic level and the fourth buffered clock signal BQCKBD is at a low logic level, while maintaining the second and fourth synchronized data signals, DM1QO and DM1QBO, at a low logic level. The first read clock transmission circuit 231 may align the first to fourth synchronized data signals DM1IO, DM1QO, DM1IBO, and DM1QBO and may output the serial data signal SDI. Accordingly, the serial data signal SDI may become a clock signal having a frequency that is twice the frequency of the first to fourth buffered clock signals BICKD, BQCKD, BICKBD, and BQCKBD. The first read clock transmission circuit 231 may output the first read clock signal RCK based on the serial data signal SDI. The second read clock transmission circuit 232 may operate in substantially the same manner as the first read clock transmission circuit 231, except that a logic level of the second dummy data DM2 is opposite to that of the first dummy data DM1.

FIG. 12C is a diagram illustrating an operation of the first data transmission circuit 241 when the semiconductor apparatus 200 operates in the monitoring mode. When the clock monitoring enable signal CMEN is enabled, the delay monitoring circuit 250 may enable the oscillating signal ROD, and the clock distribution network 220 may output the oscillating signal ROD as the first to fourth distribution clock signals ICKD, QCKD, IBCKD, and QBCKBD. When the clock monitoring enable signal CMEN is enabled, a first bit PS<1> of the phase selection signal may be set to a high logic level, and the first output data signal D1I may be fixed to a high logic level. The logic levels of the second to fourth output data signals D1Q, D1IB, and D1QB might not be defined (don't care). In an embodiment, the second to fourth output data signals D1Q, D1IB, and D1QB may also be fixed to a high logic level together with the first output data signal D1I. The second to fourth output data signals D1Q, D1IB, and D1QB may be respectively fixed to a high logic level when second to fourth bits PS<2:4> of the phase selection signal are set to a high logic level. The first data transmission circuit 241 may generate the first synchronized data signal D1IO and the serial data signal SDI corresponding to a waveform of the first distribution clock signal ICKD. Accordingly, the first data transmission circuit 241 may generate the third monitoring clock signal MCK3 by delaying the oscillating signal ROD by a delay time corresponding to the third propagation delay. The first and second read clock transmission circuits 231 and 232 may respectively generate the first and second monitoring clock signals MCK1 and MCK2 by delaying the oscillating signal ROD by delay times corresponding to the first and second propagation delays. The second to fourth data transmission circuits 242, 243, and 244 may respectively generate the fourth to sixth monitoring clock signals MCK4, MCK5, and MCK6 by delaying the oscillating signal ROD by delay times corresponding to the fourth to sixth propagation delays.

FIG. 13 illustrates a configuration of a semiconductor system 1000 in an embodiment of the present disclosure. Referring to FIG. 13, the semiconductor system 1000 may include a host device 1010 and a memory apparatus 1020. The host device 1010 may serve as a master device that controls the memory apparatus 1020, enabling it to perform various operations. The host device 1010 may access the memory apparatus 1020 to write data during a write operation and to read data stored in the memory apparatus 1020 during a read operation. For example, the host device 1010 may include at least one of or a combination of two or more of a Central Processing Unit (CPU), a Graphic Processing Unit (GPU), a Multi-Media Processor (MMP), a Digital Signal Processor (DSP), an Application Processor (AP), a Data Processing Unit (DPU), a Neural Processing Unit (NPU), and a System-on-Chip (SoC). The memory apparatus 1020 may be controlled by the host device 1010 to store data transmitted from the host device 1010 and to output data stored therein back to the host device 1010. For example, the memory apparatus 1020 may be a High Bandwidth Memory (HBM).

The host device 1010 may include an interface circuit PHY1. The host device 1010 may be coupled to the memory apparatus 1020 through the interface circuit PHY1 and may transmit various signals to and receive various signals from the memory apparatus 1020 through the interface circuit PHY1. The host device 1010 may be a component corresponding to the external device. For example, the host device 1010 may transmit command/address signals, system clock signal pairs, data clock signal pairs WCK and WCKB, strobe signals, and data to the memory apparatus 1020 through the interface circuit PHY1 and may receive strobe signals and data transmitted from the memory apparatus 1020 through the interface circuit PHY1. The memory apparatus 1020 may include a logic die 1021 and a plurality of memory dies 1022. The plurality of memory dies 1022 may be sequentially stacked on the logic die 1021 and may be electrically connected to each other through through-vias 1023 formed through the logic die 1021 and the memory dies 1022. The logic die 1021 may relay data communication between the host device 1010 and the memory dies 1022. The logic die 1021 may include an interface circuit PHY2 to connect the host device 1010 with the plurality of memory dies 1022. The interface circuit PHY2 may convert signals transmitted from the host device 1010 into signals suitable for use in the memory apparatus 1020 and may transmit the converted signals to the memory dies 1022. The interface circuit PHY2 may also convert signals output from the memory dies 1022 into signals suitable for the host device 1010 and transmit the converted signals to the host device 1010. The interface circuit PHY2 of the logic die 1021 may include the configuration of the semiconductor device 200 shown in FIG. 2. To support high bandwidth, because the memory apparatus 1020 needs to be coupled to the host device 1010 through a large number of signal transmission lines, the memory apparatus 1020 may be fabricated in a form that is stacked with the host device 1010 on a single substrate.

The semiconductor system 1000 may further include an interposer 1030 and a package substrate 1040. The interposer 1030 may be disposed on the package substrate 1040, and the host device 1010 and the memory apparatus 1020 may be disposed on the interposer 1030. The host device 1010 may be disposed on a first region (left region of FIG. 13) of the interposer 1030, and the memory apparatus 1020 may be disposed on a second region (right region of FIG. 13) of the interposer 1030. The package substrate 1040, the interposer 1030, the host device 1010, and the memory apparatus 1020 may be packaged as a single package. The package substrate 1040 may be coupled to an external device through package balls 1041, and signal paths 1042 and 1043 may be formed in the package substrate 1040 to connect the interposer 1030 to the package balls 1041. The interposer 1030 may be electrically connected to the signal paths 1042 and 1043 of the package substrate 1040 through bumps 1031.

The interposer 1030 may include a signal path 1032 to connect the host device 1010 and the memory apparatus 1020. The signal path 1032 may connect the interface circuit PHY2 of the logic die 1021 to the interface circuit PHY1 of the host device 1010. In addition, the interposer 1030 may include signal paths 1033 and 1034 to connect the host device 1010 and the memory apparatus 1020 to the package substrate 1040. The host device 1010 may be coupled to the signal path 1033 of the interposer 1030 through micro-bumps 1011, and the memory apparatus 1020 may be coupled to the signal path 1034 of the interposer 1030 through micro-bumps 1024. The logic die 1021 may be coupled to the signal path 1034 of the interposer 1030 through the micro-bumps 1024, and the plurality of memory dies 1022 may be sequentially stacked on the logic die 1021 through the micro-bumps 1024. The micro-bumps 1024 may electrically connect the through-vias of the logic die 1021 and the through-vias between the memory dies 1022. The signal path 1032 of the interposer 1030, which connects the interface circuits PHY2 and PHY1 of the logic die 1021 and the host device 1010, respectively, may be a signal transmission line, link, bus, or channel between the host device 1010 and the memory apparatus 1020. For example, the write clock signal pair WCK and WCKB, and first and second data DQ1 and DQ2 shown in FIG. 1 may be transmitted through the signal path 1032. The signal path 1033 of the interposer 1030 may be a signal transmission line, link, bus, or channel through which the host device 1010 communicates with the external device. The signal path 1034 of the interposer 1030 may be a direct access path through which the external device can directly access the memory apparatus 1020.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the provided descriptions. All changes within the meaning and range of equivalency of the claims are included within their scope.

What is claimed is:

1. A semiconductor apparatus, comprising:
a clock receiving circuit configured to receive a first write clock signal and a second write clock signal and configured to generate a first internal clock signal, a second internal clock signal, a third internal clock signal, and a fourth internal clock signal;
a clock distribution network configured to distribute the first to fourth internal clock signals as a first distribution clock signal, a second distribution clock signal, a third distribution clock signal, and a fourth distribution clock signal;
a first read clock transmission circuit configured to generate a first read clock signal based on the first to fourth distribution clock signals and first dummy data;
a first data transmission circuit configured to generate first data based on the first to fourth distribution clock signals and first internal data; and
a delay monitoring circuit configured to monitor a first propagation delay through the clock distribution network and the first read clock transmission circuit, and a second propagation delay through the clock distribution network and the first data transmission circuit and configured to individually adjust a delay time of the first read clock transmission circuit and a delay time of the first data transmission circuit.

2. The semiconductor apparatus of claim 1, wherein the clock receiving circuit is configured to divide a frequency of the first and second write clock signals to generate the first to fourth internal clock signals.

3. The semiconductor apparatus of claim 1, wherein the delay monitoring circuit is configured to adjust the delay times of the first read clock transmission circuit and the first data transmission circuit such that a difference between the first propagation delay and the second propagation delay is within a first time.

4. The semiconductor apparatus of claim 1, wherein the delay monitoring circuit is configured to form a first closed loop with the clock distribution network and the first read clock transmission circuit to monitor the first propagation delay and configured to form a second closed loop with the clock distribution network and the first data transmission circuit to monitor the second propagation delay.

5. The semiconductor apparatus of claim 1, further comprising a second read clock transmission circuit configured to generate a second read clock signal based on the first to fourth distribution clock signals and second dummy data having a logic level opposite to that of the first dummy data,
wherein the delay monitoring circuit is configured to monitor a third propagation delay through the clock distribution network and the second read clock transmission circuit and configured to adjust delay times of the first read clock transmission circuit and the second read clock transmission circuit such that the first propagation delay and the third propagation delay is substantially equal.

6. The semiconductor apparatus of claim 5, wherein the delay monitoring circuit is configured to form a first closed loop with the clock distribution network and the first read clock transmission circuit to monitor the first propagation delay and configured to form a third closed loop with the clock distribution network and the second read clock transmission circuit to monitor the third propagation delay.

7. The semiconductor apparatus of claim 1, further comprising a second data transmission circuit configured to generate second data based on the first to fourth distribution clock signals and second internal data,
wherein the delay monitoring circuit is configured to monitor a fourth propagation delay through the clock distribution network and the second data transmission circuit and configured to adjust delay times of the first data transmission circuit and the second data transmission circuit such that a difference between the second propagation delay and the fourth propagation delay is within a second time.

8. The semiconductor apparatus of claim 7, wherein the delay monitoring circuit is configured to form a second closed loop with the clock distribution network and the first data transmission circuit to monitor the second propagation delay and configured to form a fourth closed loop with the clock distribution network and the second data transmission circuit to monitor the fourth propagation delay.

9. The semiconductor apparatus, comprising:
a clock receiving circuit configured to receive a first write clock signal and a second write clock signal and configured to generate a first internal clock signal, a second internal clock signal, a third internal clock signal, and a fourth internal clock signal;
a clock distribution network configured to distribute the first to fourth internal clock signals as a first distribution clock signal, a second distribution clock signal, a third distribution clock signal, and a fourth distribution clock signal in a normal mode and configured to output an oscillating signal as the first to fourth distribution clock signals in a monitoring mode;
a first read clock transmission circuit configured to generate a first read clock signal and a first monitoring clock signal based on the first to fourth distribution clock signals and first dummy data and configured to have a delay time changed based on a first delay control signal;
a first data transmission circuit configured to generate first data and a second monitoring clock signal based on the first to fourth distribution clock signals and first internal data and configured to have a delay time changed based on a second delay control signal; and
a delay monitoring circuit configured to generate the oscillating signal based on the first and second monitoring clock signals and configured to generate the first and second delay control signals based on the oscillating signal.

10. The semiconductor apparatus of claim 9, wherein the clock receiving circuit is configured to divide a frequency of the first and second write clock signals to generate the first to fourth internal clock signals.

11. The semiconductor apparatus of claim 9, wherein the clock distribution network comprises:
a switching circuit configured to output the first to fourth internal clock signals when a clock monitoring enable signal is disabled and configured to output the oscillating signal when the clock monitoring enable signal is enabled; and
a repeater circuit configured to output the first to fourth distribution clock signals by repeating an output signal of the switching circuit.

12. The semiconductor apparatus of claim 9, wherein the first data transmission circuit comprises:
a variable delay buffer circuit configured to receive the first to fourth distribution clock signals, a phase selection signal, and the first delay control signal and configured to generate a first buffered clock signal, a second buffered clock signal, a third buffered clock signal, and a fourth buffered clock signal;
a data chopping circuit configured to generate first to fourth synchronized data signals based on the first to fourth buffered clock signals and the first internal data;
a serializer configured to serialize the first to fourth synchronized data signals and generate a serial data signal; and
a data output circuit configured to generate the first data and the first monitoring clock signal based on the serial data signal.

13. The semiconductor apparatus of claim 12, wherein the variable delay buffer circuit comprises:
a first variable delay buffer configured to buffer the first distribution clock signal based on a first bit of the phase selection signal and the first delay control signal and configured to generate the first buffered clock signal;
a second variable delay buffer configured to buffer the second distribution clock signal based on a second bit of the phase selection signal and the first delay control signal and configured to generate the second buffered clock signal;
a third variable delay buffer configured to buffer the third distribution clock signal based on a third bit of the phase selection signal and the first delay control signal and configured to generate the third buffered clock signal; and
a fourth variable delay buffer configured to buffer the fourth distribution clock signal based on a fourth bit of the phase selection signal and the first delay control signal and configured to generate the fourth buffered clock signal.

14. The semiconductor apparatus of claim 12, wherein the data chopping circuit comprises:
a first chopping circuit configured to generate the first synchronized data signal from a first output data signal in synchronization with the first and second buffered clock signals;
a second chopping circuit configured to generate the second synchronized data signal from a second output data signal in synchronization with the second and third buffered clock signals;
a third chopping circuit configured to generate the third synchronized data signal from a third output data signal in synchronization with the third and fourth buffered clock signals; and
a fourth chopping circuit configured to generate the fourth synchronized data signal from a fourth output data signal in synchronization with the fourth and first buffered clock signals.

15. The semiconductor apparatus of claim 12, wherein the data output circuit comprises:
a pre-driver configured to generate an up-down driving signal based on the serial data signal and configured to provide the up-down driving signal as the first monitoring clock signal; and
a main driver configured to generate the first data based on the up-down driving signal.

16. The semiconductor apparatus of claim 12, wherein the data output circuit comprises:
a pre-driver configured to generate an up-down driving signal based on the serial data signal;
a replica pre-driver configured to generate the first monitoring clock signal based on the serial data signal; and
a main driver configured to generate the first data based on the up-down driving signal.

17. The semiconductor apparatus of claim 9, wherein the delay monitoring circuit comprises:
a selection circuit configured to output one of the first and second monitoring clock signals as an oscillating input signal based on a selection signal;
an oscillating signal generation circuit configured to generate the oscillating signal based on a clock monitoring enable signal and the oscillating input signal; and
a delay control circuit configured to count the oscillating signal and generate the first and second delay control signals based on a count value.

18. The semiconductor apparatus of claim 17, wherein the oscillating signal generation circuit is configured to transition the oscillating signal from a second logic level to a first logic level based on the clock monitoring enable signal, generate a set pulse signal based on the oscillating input signal, transition the oscillating signal from the first logic level to the second logic level based on the set pulse signal, delay the set pulse signal to generate a reset pulse signal, and transition the oscillating signal from the second logic level to the first logic level based on the reset pulse signal.

19. The semiconductor apparatus of claim 17, wherein the oscillating signal generation circuit comprises:
a set pulse generation circuit configured to generate a set pulse signal based on the oscillating input signal;
a reset pulse generation circuit configured to generate a reset pulse signal based on the set pulse signal; and
an oscillating driver configured to be activated based on the clock monitoring enable signal and configured to drive the oscillating signal with a first supply voltage based on the set pulse signal and drive the oscillating signal with a second supply voltage based on the reset pulse signal.

20. The semiconductor apparatus of claim 19, further comprising a delay circuit configured to delay the set pulse signal and generate a delayed set pulse signal,
wherein the reset pulse generation circuit is configured to receive the delayed set pulse signal and generate the reset pulse signal.

21. The semiconductor apparatus of claim 9, further comprising a second read clock transmission circuit configured to generate a second read clock signal and a third monitoring clock signal based on the first to fourth distribution clock signals and second dummy data having a logic level opposite to that of the first dummy data, and configured to have a delay time changed based on a third delay control signal,
wherein the delay monitoring circuit is configured to generate the oscillating signal based on the third monitoring clock signal and configured to further generate the third delay control signal based on the oscillating signal.

22. The semiconductor apparatus of claim 21, further comprising a second data transmission circuit configured to generate second data and a fourth monitoring clock signal based on the first to fourth distribution clock signals and second internal data, and configured to have a delay time changed based on a fourth delay control signal,
wherein the delay monitoring circuit is configured to generate the oscillating signal based on the fourth monitoring clock signal and configured to further generate the fourth delay control signal based on the oscillating signal.
